(19) United States
(12) Patent Application Publication
(10) Pub. No.: US 2025/0297110 A1
(43) Pub. Date: Sep. 25, 2025

(54) RESIN FILM, PRINTED WIRING BOARD, AND SEMICONDUCTOR PACKAGE

(71) Applicant: Resonac Corporation, Minato-ku, Tokyo (JP)

(72) Inventors: Takuji IKEYA, Minato-ku, Tokyo (JP); Hiroki KUZUOKA, Minato-ku, Tokyo (JP); Shota SHIMADA, Minato-ku, Tokyo (JP); Tomohiko KOTAKE, Minato-ku, Tokyo (JP)

(21) Appl. No.: 18/859,278

(22) PCT Filed: Dec. 25, 2023
(86) PCT No.: PCT/JP2023/046418

§ 371 Date: Oct. 23, 2024

(30) Foreign Application Priority Data
Dec. 28, 2022 (JP) 2022-212326

(51) Int. Cl. C09D 5/00; C08J 7/04; C08J 7/043; C09D 153/02; H01L 23/14; H05K 1/03

(52) U.S. Cl. CPC C09D 5/002; C08J 7/042; C08J 7/043; C09D 153/02; H01L 23/145; H05K 1/036; H05K 1/0373; C08J 2435/02; C08J 2453/02; C08J 2479/08; H05K 2201/0209

(57) ABSTRACT

The embodiment relates to a resin film including: an insulation-member-forming resin layer containing a first resin composition; and a primer-layer-forming resin layer provided on one side of the insulation-member-forming resin layer and containing a second resin composition, the first resin composition containing a thermosetting resin (A), a compound that is in a liquid state at 25° C., has a reactive group, and has a molecular weight of 1,000 or less (B), and an inorganic filler (C), as well as a printed wiring board and a semiconductor package, in each of which the resin film is used.

### TECHNICAL FIELD

The embodiment relates to a resin film, a printed wiring board, and a semiconductor package.

### BACKGROUND ART

Miniaturization and increasing performance of electronic devices in recent years have also moved the fields of printed wiring boards and semiconductor packages toward higher wiring density and integration.

In an electronic device as such, an insulating material such as a thermosetting resin is used as an encapsulating material for a semiconductor chip, a substrate material for a printed wiring board, and the like; however, stress generated due to a difference in thermal expansion coefficient between the insulating material and the semiconductor chip can be a problem. The generated stress may cause a warpage of a semiconductor package, resulting in a decrease in reliability.

As a method for bringing the thermal expansion coefficient of an insulating material closer to the thermal expansion coefficient of a semiconductor chip, a method of blending an inorganic filler with the insulating material is being practiced.

PTL 1 discloses a technique of blending a polybutadiene-based elastomer modified with an acid anhydride in a thermosetting resin composition containing an inorganic filler and a polyimide compound having a structural unit derived from a maleimide resin having at least two N-substituted maleimide groups and a structural unit derived from a diamine compound with an aim of providing a thermosetting resin composition having low dielectric loss tangent, low thermal expansibility, and excellent wiring-embeddability and flatness.

### Citation List

### Patent Document

[PTL 1] JP 2018-012747 A

### SUMMARY OF THE INVENTION

### Problems to be Solved by the Invention

Meanwhile, a thermosetting resin film containing a thermosetting resin and the like may be used as an insulating material. The resin film may be cured while embedding a circuit of a circuit substrate to thus be used for forming an insulation layer or as an encapsulating material of a semiconductor chip, for example.

While the thermosetting resin composition of PTL 1 is excellent in dielectric loss tangent, low thermal expansivity, wiring-embeddability, and the like, when it is formed into a thick resin film, there are cases where a crack develops. This problem is likely to arise particularly when a thermosetting resin that allows easily achieving high heat resistance is used or when an inorganic filler that contributes to low thermal expansivity is used. To solve the problem, improving flexibility of the resin film is considered to be effective.

As a method for improving flexibility of a resin film, a method of causing such a small amount of an organic solvent that allows maintaining a solid state to be contained in the resin film is conceivable. However, during heating and curing of the resin film containing the small amount of the organic solvent, volatilization of the organic solvent may develop a void in a cured product or roughen the surface of the cured product. Since the organic solvent volatilizes during heating and curing, a need for creating a safer work environment also arises. The thicker the resin film is, the more significant these problems become, and therefore improvement is desired.

Metal plating for forming a circuit may be applied to a cured product of a resin film in some cases. Accordingly, a cured product of a resin film is required to have a favorable plating property that allows forming a plated layer free from blister, peeling, and the like. However, according to studies conducted by the present inventors, it is found that there are cases where a resin film improved in flexibility fails to provide a sufficient plating property.

In view of these circumstances, an object of the embodiment is to provide a resin film that can form a cured product having an excellent plating property and, while being excellent in flexibility, can suppress generation of a volatile component during heating and curing, as well as a printed wiring board and a semiconductor package, in each of which the resin film is used.

### Means for Solving the Problems

The present inventors have conducted studies to solve the aforementioned problems, and as a result found that the problems can be solved by the following embodiment.

Specifically, the embodiment relates to [1] to below.

[1] A resin film including: an insulation-member-forming resin layer containing a first resin composition; and
a primer-layer-forming resin layer provided on one side of the insulation-member-forming resin layer and containing a second resin composition,
the first resin composition containing a thermosetting resin (A), a compound that is in a liquid state at 25° C., has a reactive group, and has a molecular weight of 1,000 or less (B), and an inorganic filler (C).

[2] The resin film according to [1], in which the component (A) is one or more selected from a group consisting of a maleimide resin having one or more N-substituted maleimide groups and a derivative of the maleimide resin.

[3] The resin film according to [2], in which the maleimide resin having one or more N-substituted maleimide groups is a maleimide resin containing a condensed ring of an aromatic ring and an aliphatic ring in a molecular structure and having two or more N-substituted maleimide groups.

[4] The resin film according to any one of [1] to [3], in which the component (B) has, as the reactive group, one or more selected from a functional group having an ethylenically unsaturated bond, an epoxy group, a hydroxy group, a carboxy group, and an amino group.

[5] The resin film according to any one of [1] to [4], in which the component (B) has two or more of the reactive groups in one molecule.

[6] The resin film according to any one of [1] to [5], in which the component (B) is a di(meth)acrylate.

[7] The resin film according to any one of [1] to [6], in which a content of the component (B) relative to a total solid content (100 mass %) of the first resin composition is 0.5 to 20 mass %.

[8] The resin film according to any one of [1] to [7], in which the second resin composition contains an inorganic filler (H), and
a content by mass of the inorganic filler (H) in the second resin composition is smaller than a content by mass of the inorganic filler (C) in the first resin composition.

[9] The resin film according to [8], in which the second resin composition further contains a thermosetting resin (F) and a compound that is in a liquid state at 25° C., has a reactive group, and has a molecular weight of 1,000 or less (G).

The resin film according to any one of [1] to [9], in which the insulation-member-forming resin layer has a thickness of 80 μm or more.

The resin film according to any one of [1] to [10], in which the primer-layer-forming resin layer has a thickness of 0.2 to 20 μm.

The resin film according to any one of [1] to [11], the resin film having a mass reduction rate during heating and drying in an air atmosphere at 170° C. for 30 minutes of 2.0 mass % or less.

A printed wiring board including a cured product of the resin film according to any one of [1] to [12].

A semiconductor package including a cured product of the resin film according to any one of [1] to [12].

### Advantageous Effects of Invention

The embodiment can provide a resin film that can form a cured product having an excellent plating property and, while being excellent in flexibility, can suppress generation of a volatile component during heating and curing, as well as a printed wiring board and a semiconductor package, in each of which the resin film is used.

### DESCRIPTION OF THE EMBODIMENTS

In the present specification, a numerical value range expressed using “to” indicates a range including the numerical values placed before and after “to” as the minimum value and the maximum value, respectively.

For example, the notation of a numerical value range “X to Y” (X and Y are real numbers) means the numerical value range of X or more and Y or less. The phrase “X or more” in the present specification means X and numerical values greater than X. The phrase “Y or less” in the present specification means Y and numerical values smaller than Y.

The lower limit value and the upper limit value of a numerical value range described in the present specification are each appropriately combined with the lower limit value or the upper limit value of another numerical value range.

In a numerical value range described in the present specification, the lower limit value or the upper limit value of the numerical value range may be replaced by a value shown in Examples.

Each of components and materials exemplified in the present specification may be used alone, or may be used in combination of two or more types unless otherwise specified.

In the present specification, the content of each component in a resin composition means, when there are a plurality of substances corresponding to the component in the resin composition, a total amount of the plurality of substances present in the resin composition unless otherwise specified.

In the present specification, a “resin composition” means a mixture of two or more components containing at least a resin and, when the resin is a thermosetting resin, also encompasses the mixture cured to B-stage. It should be noted that the type and content of each component in the resin composition in B-stage means the type and content of the component before cured to B-stage, that is, the type and blending amount of the component blended to produce the resin composition.

In the present specification, where a “layer” is referred to, the “layer” encompasses not only aspects in which it is a solid layer but also aspects in which it partially forms an island-like pattern, aspects in which it has a hole, and aspects in which an interface with an adjacent layer is unclear.

In the present specification, “solid content” means components other than solvents and encompasses those in a liquid state, a starch-syrup-like state, and a waxy state at room temperature. The room temperature in the present specification indicates 25° C.

In the present specification, “(meth)acrylate” means “acrylate” and “methacrylate” corresponding to it. Similarly, “(meth)acryl” means “acryl” and “methacryl” corresponding to it, and “(meth)acryloyl” means “acryloyl” and “methacryloyl” corresponding to it.

In the present specification, “molecular weight” of a compound means, when the compound is not a polymer and has a structural formula that can be specified, a molecular weight that can be calculated from the structural formula; when the compound is a polymer, it means a number average molecular weight.

A number average molecular weight in the present specification means a value measured as a polystyrene-equivalent value by gel permeation chromatography (GPC). Specifically, a number average molecular weight in the present specification can be measured by the method described in Examples.

The action mechanism described in the present specification is conjecture, and does not limit a mechanism that achieves the effect of the resin composition according to the embodiment.

The embodiment also encompasses aspects in which matters described in the present specification are combined as appropriate.

### [Resin Film]

A resin film of the embodiment is a resin film including:
an insulation-member-forming resin layer containing a first resin composition; and
a primer-layer-forming resin layer provided on one side of the insulation-member-forming resin layer and containing a second resin composition,
the first resin composition containing a thermosetting resin (A), a compound that is in a liquid state at 25° C., has a reactive group, and has a molecular weight of 1,000 or less (B), and an inorganic filler (C).

In the present specification, the components may be abbreviated as the component (A), the component (B), etc., and other components may also be abbreviated similarly.

The compound (B) that is in a liquid state at 25° C., has a reactive group, and has a molecular weight of 1,000 or less may be referred to as “reactive liquid compound (B).”

In the embodiment, being in a liquid state at 25° C. means that a viscosity obtained with the following measurement method is 100,000 mPa·s or less.

### <Viscosity Measuring Method>

Device: E-type viscometer
Cone rotor: 1°34′×R24
Temperature: 25° C.
Sample amount: 1.0 mL
Rotation speed: 20 rpm

In the present specification, a viscosity at 25° C. means the viscosity measured using the aforementioned method.

The reason why the resin film of the embodiment can form a cured product having an excellent plating property and, while being excellent in flexibility, can suppress generation of a volatile component during heating and curing is presumed as follows.

The first resin composition contained in the insulation-member-forming resin layer in the resin film of the embodiment contains the compound that is in a liquid state at 25° C. and has a molecular weight of 1,000 or less (B) as a component that improves flexibility of the first resin composition. Since the reactive liquid compound (B) is a liquid component having a relatively low molecular weight, it can be considered that the reactive liquid compound (B) can properly enter between resin component molecules and effectively weaken the interaction between the resin component molecules, thereby improving flexibility of the resin film.

In addition, since the reactive liquid compound (B) has a reactive group, the reactive liquid compound (B) can react with the reactive liquid compound (B) or other component during heating and curing of the thermosetting resin (A). That is, the reactive liquid compound (B) suppresses volatilization by its curing reaction while simultaneously contributing to improvement in flexibility. Therefore, it can be considered that the resin film of the embodiment can improve flexibility while suppressing generation of a volatile component, as compared with a case where an organic solvent or the like is used as a component for improving flexibility.

Furthermore, the resin film of the embodiment has the primer-layer-forming resin layer provided on one side of the insulation-member-forming resin layer and containing the second resin composition. It can be presumed that a cured product of the resin film of the embodiment thus has a primer layer on its surface, resulting in improvement in plating property.

### <<Insulation-Member-Forming Resin Layer>>

It is preferable that the insulation-member-forming resin layer in the resin film of the embodiment contain the first resin composition and the first resin composition be formed as a layer.

The first resin composition contains the thermosetting resin (A), the compound that is in a liquid state at 25° C., has a reactive group, and has a molecular weight of 1,000 or less (B), and the inorganic filler (C).

Each component that may be contained in the first resin composition is described below in turn.

### <Thermosetting Resin (A)>

The first resin composition contains the thermosetting resin (A).

The thermosetting resin (A) may be used alone, or may be used in combination of two or more types.

Examples of the thermosetting resin (A) include an epoxy resin, a phenol resin, a maleimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin.

Among them, from the viewpoint of heat resistance, the thermosetting resin (A) is preferably a maleimide resin, and more preferably one or more selected from a group consisting of a maleimide resin having one or more N-substituted maleimide groups and a derivative of the maleimide resin.

In the following description, “one or more selected from a group consisting of a maleimide resin having one or more N-substituted maleimide groups and a derivative of the maleimide resin” may be referred to as “maleimide-based resin.”

In the following description, a maleimide resin having one or more N-substituted maleimide groups may be referred to as “maleimide resin (AX)” or “component (AX).”

A derivative of a maleimide resin having one or more N-substituted maleimide groups may be referred to as “maleimide resin derivative (AY)” or “component (AY).”

### (Maleimide Resin (AX))

The maleimide resin (AX) is not particularly limited as long as it is a maleimide resin having one or more N-substituted maleimide groups.

From the viewpoint of conductor adhesion properties and heat resistance, the maleimide resin (AX) is preferably an aromatic maleimide resin having two or more N-substituted maleimide groups, and more preferably an aromatic bismaleimide resin having two N-substituted maleimide groups.

In the present specification, an “aromatic maleimide resin” means a compound having an N-substituted maleimide group directly bonded to an aromatic ring. In the present specification, an “aromatic bismaleimide resin” means a compound having two N-substituted maleimide groups directly bonded to an aromatic ring. In the present specification, an “aromatic polymaleimide resin” means a compound having three or more N-substituted maleimide groups directly bonded to an aromatic ring.

In the present specification, an “aliphatic maleimide resin” means a compound having an N-substituted maleimide group directly bonded to an aliphatic hydrocarbon.

From the viewpoint of dielectric properties, conductor adhesion properties, and heat resistance, the maleimide resin (AX) is preferably a maleimide resin containing a condensed ring of an aromatic ring and an aliphatic ring in a molecular structure and having two or more N-substituted maleimide groups [hereinafter sometimes referred to as “maleimide resin (A1)” or “component (A1).”].

### [Maleimide Resin (A1)]

From the viewpoint of dielectric properties, conductor adhesion properties, and heat resistance, the maleimide resin (A1) is preferably an aromatic maleimide resin containing a condensed ring of an aromatic ring and an aliphatic ring in a molecular structure and having two or more N-substituted maleimide groups.

The maleimide resin (A1) is more preferably an aromatic bismaleimide resin containing a condensed ring of an aromatic ring and an aliphatic ring in a molecular structure and having two N-substituted maleimide groups.

From the viewpoint of dielectric properties, conductor adhesion properties, and ease of manufacture, the condensed ring in the maleimide resin (A1) preferably has a condensed bicyclic structure, and more preferably is an indane ring.

The maleimide resin (A1) containing an indane ring is preferably an aromatic bismaleimide resin containing an indane ring.

In the present specification, an indane ring means a condensed bicyclic structure of an aromatic six-membered ring and a saturated aliphatic five-membered ring. At least one carbon atom among the ring-forming carbon atoms that form the indane ring has a bonding group for bonding to another group constituting the maleimide resin (A1). The ring-forming carbon atom having the bonding group and the other ring-forming carbon atoms need not to have, in addition the aforementioned bonding group, a bonding group, a substituent, or the like, but preferably have a bonding group other than the aforementioned bonding group to thereby form a divalent group.

In the maleimide resin (A1), the indane ring is preferably contained as a divalent group represented by the following general formula (A1-1).

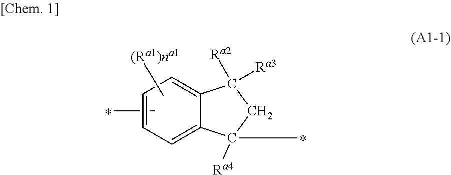

wherein R^{a1} is an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a hydroxy group, or a mercapto group; n^{a1} is an integer of 0 to 3; R^{a2} to R^{a4} are each independently an alkyl group having 1 to 10 carbon atoms; and * represents a bonding site.

Examples of the alkyl group having 1 to 10 carbon atoms represented by R^{a1} in the general formula (A1-1) include a methyl group, an ethyl group, a propyl group, a butyl group, a pentyl group, a hexyl group, a heptyl group, an octyl group, a nonyl group, and a decyl group. These alkyl groups may be linear or branched.

Examples of the alkyl group contained in the alkyloxy group having 1 to 10 carbon atoms and the alkylthio group having 1 to 10 carbon atoms represented by R^{a1} are the same as those of the alkyl group having 1 to 10 carbon atoms mentioned above.

Examples of the aryl group having 6 to 10 carbon atoms represented by R^{a1} include a phenyl group and a naphthyl group.

Examples of the aryl group contained in the aryloxy group having 6 to 10 carbon atoms and the arylthio group having 6 to 10 carbon atoms represented by R^{a1} are the same as those of the aryl group having 6 to 10 carbon atoms mentioned above.

Examples of the cycloalkyl group having 3 to 10 carbon atoms represented by R^{a1} include a cyclopropyl group, a cyclobutyl group, a cyclopentyl group, a cyclohexyl group, a cycloheptyl group, a cyclooctyl group, a cyclononyl group, and a cyclodecyl group.

When n^{a1} in the general formula (A1-1) is an integer of 1 to 3, from the viewpoint of solvent solubility and reactivity, R^{a1} is preferably an alkyl group having 1 to 4 carbon atoms, a cycloalkyl group having 3 to 6 carbon atoms, or an aryl group having 6 to 10 carbon atoms, and more preferably an alkyl group having 1 to 4 carbon atoms.

Examples of the alkyl group having 1 to 10 carbon atoms represented by R^{a2} to R^{a4} are the same as those of R^{a1} mentioned above. Among them, R^{a2} to R^{a4} are each preferably an alkyl group having 1 to 4 carbon atoms, more preferably a methyl group or an ethyl group, and further preferably a methyl group.

In the general formula (A1-1), n^{a1} is an integer of 0 to 3 and, when n^{a1} is 2 or 3, a plurality of R^{a1}s may be the same as or different from each other.

Among the foregoing, from the viewpoint of ease of manufacture, the divalent group represented by the general formula (A1-1) is preferably a divalent group represented by the following general formula (A1-1a) in which n^{a1} is 0 and R^{a2} to R^{a4} are methyl groups, and more preferably a divalent group represented by the following general formula (A1-1a′) or a divalent group represented by the following general formula (A1-1a″).

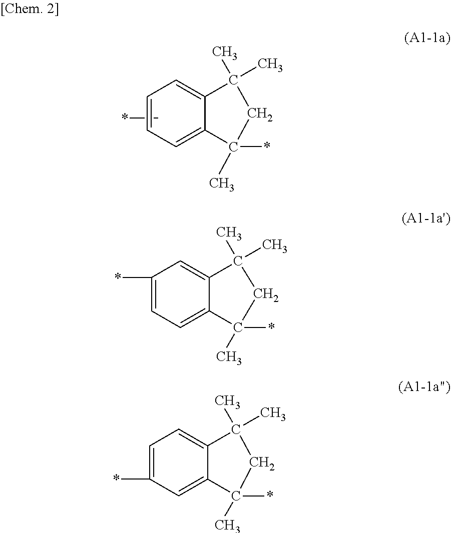

wherein * represents a bonding site.

From the viewpoint of dielectric properties, conductor adhesion properties, heat resistance, and ease of manufacture, the maleimide resin (A1) containing the divalent group represented by the general formula (A1-1) is preferably one represented by the following general formula (A1-2).

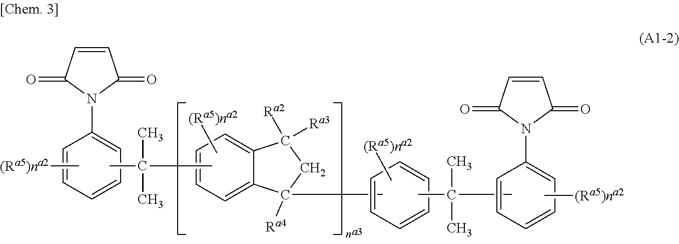

wherein R^{a1}s to R^{a4} and n^{a1}s are the same as those in the general formula (A1-1); R^{a5}s are each independently an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxy group, or a mercapto group; n^{a2}s are each independently an integer of 0 to 4; and n^{a3} is a number of 0.95 to 10.0.

In the general formula (A1-2), a plurality of R^{a1}s, a plurality of n^{a1}s, a plurality of R^{a5}s, and a plurality of n^{a2}s may each be the same as or different from each other.

When n^{a3} is more than 1, a plurality of R^{a2}s, a plurality of R^{a3}s, and a plurality of R^{a4}s may each be the same as or different from each other.

Examples of the alkyl group having 1 to 10 carbon atoms, the alkyloxy group having 1 to 10 carbon atoms, the alkylthio group having 1 to 10 carbon atoms, the aryl group having 6 to 10 carbon atoms, the aryloxy group having 6 to 10 carbon atoms, the arylthio group having 6 to 10 carbon atoms, and the cycloalkyl group having 3 to 10 carbon atoms represented by R^{a5} in the general formula (A1-2) are the same as those of R^{a1} mentioned above, and the same applies to preferred examples.

In the general formula (A1-2), n^{a2} is an integer of 0 to 4, and from the viewpoint of compatibility with other resins, dielectric properties, conductor adhesion properties, and ease of manufacture, it is preferably an integer of 1 to 3, more preferably 2 or 3, and further preferably 2.

When n^{a2} is 1 or more, a benzene ring and an N-substituted maleimide group form a staggered conformation, and solvent solubility tends to be further improved by suppression of intermolecular stacking. When n^{a2} is 1 or more, from the viewpoint of suppression of intermolecular stacking, the substitution position of R^{a5} is preferably an ortho position with respect to the N-substituted maleimide group.

From the viewpoint of dielectric properties, conductor adhesion properties, solvent solubility, ease of handling, and heat resistance, n^{a3} in the general formula (A1-2) is preferably a number of 0.98 to 8.0, more preferably a number of 1.0 to 7.0, and further preferably a number of 1.1 to 6.0. Meanwhile, n^{a3} represents the average number of structural units each containing an indane ring.

From the viewpoint of dielectric properties, conductor adhesion properties, solvent solubility, and ease of manufacture, the maleimide resin (A1) represented by the general formula (A1-2) is more preferably one represented by the following general formula (A1-3) or one represented by the following general formula (A1-4).

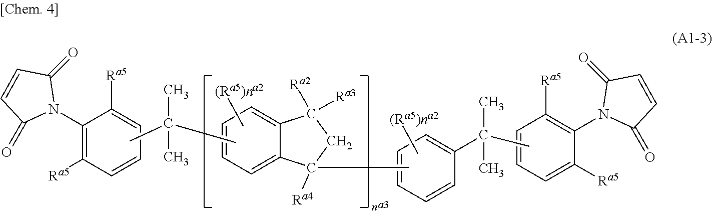

wherein R^{a1}s to R^{a5}s, n^{a1}s, and n^{a3} are the same as those in the general formula (A1-2).

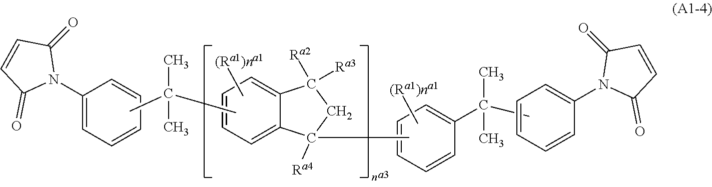

wherein R^{a1}s to R^{a4}, n^{a1}s, and n^{a3} are the same as those in the general formula (A1-2).

Examples of the maleimide resin (A1) represented by the general formula (A1-3) include a maleimide resin represented by the following general formula (A1-3-1), a maleimide resin represented by the following general formula (A1-3-2), and a maleimide resin represented by the following general formula (A1-3-3).

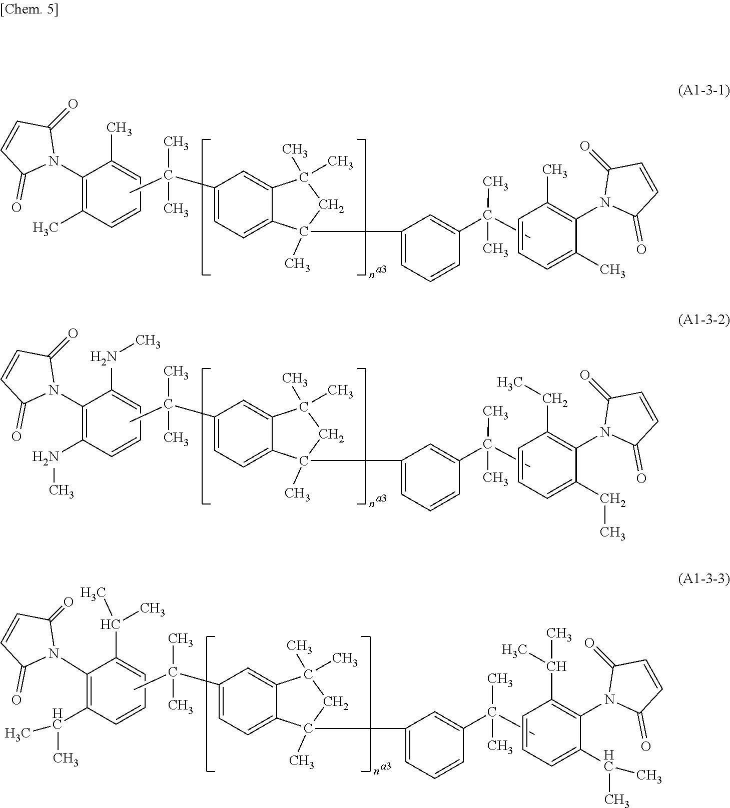

wherein n^{a3} is the same as that in the general formula (A1-2).

From the viewpoint of dielectric properties, conductor adhesion properties, solvent solubility, and ease of manufacture, the maleimide resin (A1) represented by the general formula (A1-4) is more preferably one represented by the following general formula (A1-4-1).

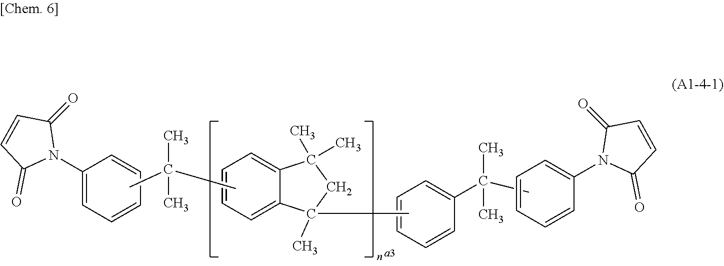

wherein n^{a3} is the same as that in the general formula (A1-2).

The number average molecular weight of the maleimide resin (A1) is not particularly limited, but from the viewpoint of compatibility with other resins, conductor adhesion properties, and heat resistance, it is preferably 600 to 3,000, more preferably 800 to 2,000, and further preferably 1,000 to 1,500.

The maleimide resin (AX) may be a maleimide resin (A2) [hereinafter sometimes referred to as “maleimide resin (A2)” or “component (A2).”] other than the maleimide resin (A1) mentioned above.

### [Maleimide Resin (A2)]

The maleimide resin (A2) is preferably a maleimide resin represented by the following general formula (A2-1).

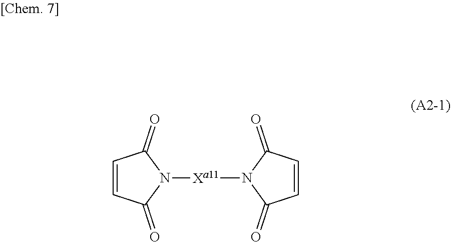

wherein X^{a11} is a divalent organic group containing no condensed ring of an aromatic ring and an aliphatic ring.

X^{a11} in the general formula (A2-1) is a divalent organic group containing no condensed ring of an aromatic ring and an aliphatic ring.

Examples of the divalent organic group represented by X^{a11} in the general formula (A2-1) include a divalent group represented by the following general formula (A2-2), a divalent group represented by the following general formula (A2-3), a divalent group represented by the following general formula (A2-4), a divalent group represented by the following general formula (A2-5), and a divalent group represented by the following general formula (A2-6).

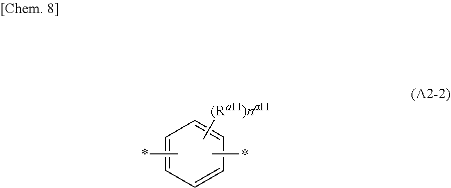

wherein R^{a11} is an aliphatic hydrocarbon group having 1 to 5 carbon atoms or a halogen atom; n^{a11} is an integer of 0 to 4; and * represents a bonding site.

Examples of the aliphatic hydrocarbon group having 1 to 5 carbon atoms represented by R^{a11} in the general formula (A2-2) include an alkyl group having 1 to 5 carbon atoms such as a methyl group, an ethyl group, a n-propyl group, an isopropyl group, a n-butyl group, an isobutyl group, a t-butyl group, or a n-pentyl group; an alkenyl group having 2 to 5 carbon atoms, and an alkynyl group having 2 to 5 carbon atoms. The aliphatic hydrocarbon group having 1 to 5 carbon atoms may be linear or branched. The aliphatic hydrocarbon group having 1 to 5 carbon atoms is preferably an aliphatic hydrocarbon group having 1 to 3 carbon atoms, more preferably an alkyl group having 1 to 3 carbon atoms, and further preferably a methyl group.

Examples of the halogen atom include a fluorine atom, a chlorine atom, a bromine atom, and an iodine atom.

In the general formula (A2-2), n^{a11} is an integer of 0 to 4 and, from the viewpoint of availability, preferably an integer of 0 to 2, more preferably 0 or 1, and further preferably 0.

When n^{a11} is an integer of 2 or more, a plurality of R^{a11}s may be the same as or different from each other.

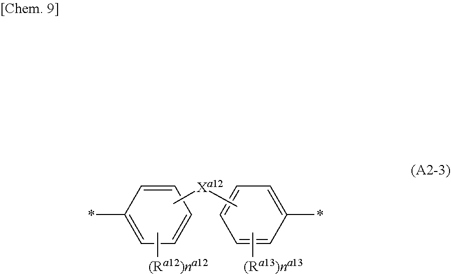

wherein R^{a12} and R^{a13} are each independently an aliphatic hydrocarbon group having 1 to 5 carbon atoms or a halogen atom; X^{a12} is an alkylene group having 1 to 5 carbon atoms, an alkylidene group having 2 to 5 carbon atoms, an ether group, a sulfide group, a sulfonyl group, a carbonyloxy group, a keto group, a single bond, or a divalent group represented by the following general formula (A2-3-1); n^{a12} and n^{a13} are each independently an integer of 0 to 4; and * represents a bonding site.

Examples of the aliphatic hydrocarbon group having 1 to 5 carbon atoms and the halogen atom represented by R^{a12} and R^{a13} in the general formula (A2-3) are the same as those of R^{a11} mentioned above.

Examples of the alkylene group having 1 to 5 carbon atoms represented by X^{a12} in the general formula (A2-3) include a methylene group, a 1,2-dimethylene group, a 1,3-trimethylene group, a 1,4-tetramethylene group, and a 1,5-pentamethylene group.

Examples of the alkylidene group having 2 to 5 carbon atoms represented by X^{a12} in the general formula (A2-3) include an ethylidene group, a propylidene group, an isopropylidene group, a butylidene group, an isobutylidene group, a pentylidene group, and an isopentylidene group.

In the general formula (A2-3), n^{a12} and n^{a13} are each independently an integer of 0 to 4 and, from the viewpoint of availability, compatibility with other resins, and suppression of gelation of a product during the reaction, preferably an integer of 1 to 3, more preferably 1 or 2, and further preferably 2.

When n^{a12} or n^{a13} is an integer of 2 or more, a plurality of R^{a12}s or a plurality of R^{a13}s may each be the same as or different from each other.

The divalent group represented by the general formula (A2-3-1), which is represented by X^{a12} in the general formula (A2-3), is as follows.

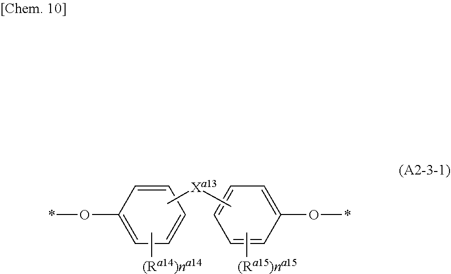

wherein R^{a14} and R^{a15} are each independently an aliphatic hydrocarbon group having 1 to 5 carbon atoms or a halogen atom; X^{a13} is an alkylene group having 1 to 5 carbon atoms, an alkylidene group having 2 to 5 carbon atoms, an ether group, a sulfide group, a sulfonyl group, a carbonyloxy group, a keto group, or a single bond; n^{a14} and n^{a15} are each independently an integer of 0 to 4; and * represents a bonding site.

Examples of the aliphatic hydrocarbon group having 1 to 5 carbon atoms and the halogen atom represented by R^{a14} and R^{a15} in the general formula (A2-3-1) are the same as those of R^{a11} mentioned above.

Examples of the alkylene group having 1 to 5 carbon atoms and the alkylidene group having 2 to 5 carbon atoms represented by X^{a13} in the general formula (A2-3-1) are the same as those of X^{a12} mentioned above.

In the general formula (A2-3-1), n^{a14} and n^{a15} are each independently an integer of 0 to 4 and, from the viewpoint of availability, preferably an integer of 0 to 2, more preferably 0 or 1, and further preferably 0.

When n^{a14} or n^{a15} is an integer of 2 or more, a plurality of R^{a14}s or a plurality of R^{a15}s may be the same as or different from each other.

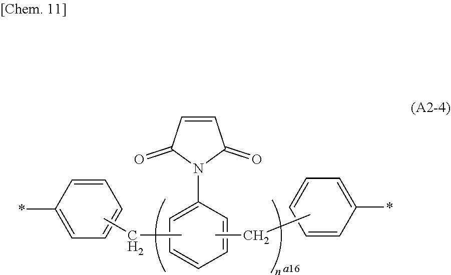

wherein n^{a16} is an integer of 0 to 10; and * represents a bonding site.

From the viewpoint of availability, n^{a16} in the general formula (A2-4) is preferably an integer of 0 to 5, more preferably an integer of 0 to 4, and further preferably an integer of 0 to 3.

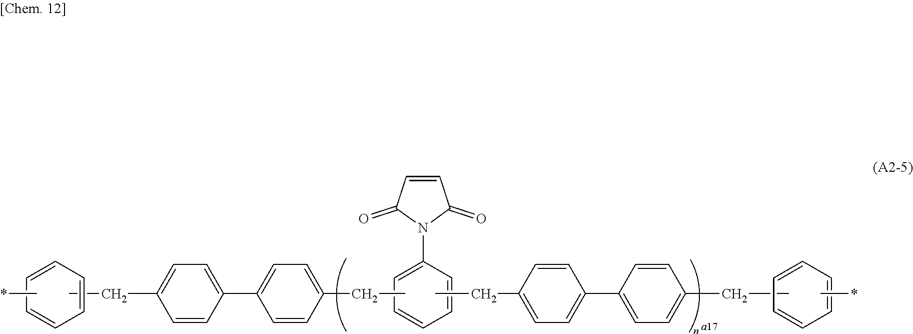

wherein n^{a17} is a number of 0 to 5; and * represents a bonding site.

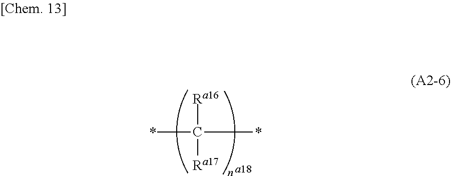

wherein R^{a16} and R^{a17} are each independently a hydrogen atom or an aliphatic hydrocarbon group having 1 to 5 carbon atoms; n^{a18} is an integer of 1 to 8; and * represents a bonding site.

Examples of the aliphatic hydrocarbon group having 1 to 5 carbon atoms represented by R^{a16} and R^{a17} in the general formula (A2-6) are the same as those of R^{a11} mentioned above.

In the general formula (A2-6), n^{a18} is an integer of 1 to 8, preferably an integer of 1 to 5, more preferably an integer of 1 to 3, and further preferably 1. When n^{a18} is an integer of 2 or more, a plurality of Rales or a plurality of R^{a17}s may each be the same as or different from each other.

The maleimide resin (A2) is preferably a polymaleimide resin represented by the following general formula (A2-7).

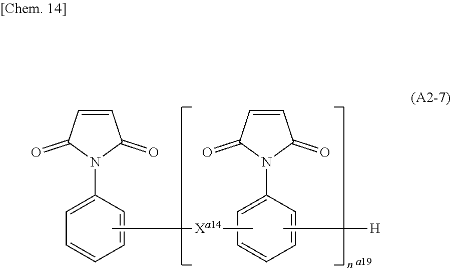

wherein X^{a14}s are each independently a divalent hydrocarbon group having 1 to 20 carbon atoms; and n^{a19} is an integer of 2 to 5.

Examples of the divalent hydrocarbon group having 1 to 20 carbon atoms represented by X^{a14} in the general formula (A2-7) include a divalent aliphatic hydrocarbon group such as an alkylene group having 1 to 5 carbon atoms or an alkylidene group having 2 to 5 carbon atoms; and a divalent hydrocarbon group including an aromatic hydrocarbon group represented by the following general formula (A2-8).

Examples of the alkylene group having 1 to 5 carbon atoms include a methylene group, a 1,2-dimethylene group, a 1,3-trimethylene group, a 1,4-tetramethylene group, and a 1,5-pentamethylene group. The alkylene group having 1 to 5 carbon atoms is preferably an alkylene group having 1 to 3 carbon atoms, more preferably an alkylene group having 1 or 2 carbon atoms, and further preferably a methylene group.

The alkylidene group having 2 to 5 carbon atoms is preferably an alkylidene group having 2 to 4 carbon atoms, more preferably an alkylidene group having 2 or 3 carbon atoms, and further preferably an isopropylidene group.

[Chem. 15]

*-X^{a15}_Ar^{a1}_X^{a16}_* (A2-8)

wherein Ar^{a1} is a divalent aromatic hydrocarbon group; X^{a15} and X^{a16} are each independently a divalent aliphatic hydrocarbon group having 1 to 5 carbon atoms; and * represents a bonding site.

Examples of the divalent aliphatic hydrocarbon group having 1 to 5 carbon atoms represented by X^{a15} and X^{a16} in the general formula (A2-8) include an alkylene group having 1 to 5 carbon atoms and an alkylidene group having 2 to 5 carbon atoms and are the same as those of X^{a14} in the general formula (A2-7). Among them, a methylene group is preferred. Examples of the divalent aromatic hydrocarbon group represented by Aral in the general formula (A2-8) include a phenylene group, a naphthylene group, a biphenylene group, and an anthranylene group. Among them, a biphenylene group is preferred. Examples of the biphenylene group include a 4,2′-biphenylene group, a 4,3′-biphenylene group, a 4,4′-biphenylene group, and a 3,3′-biphenylene group; among them, a 4,4′-biphenylene group is preferred.

Among the above options, X^{a14} in the general formula (A2-7) is preferably a divalent hydrocarbon group including an aromatic hydrocarbon group represented by the general formula (A2-8), and more preferably a divalent hydrocarbon group represented by the general formula (A2-8) in which X^{a15} and X^{a16} are methylene groups and Aral is a 4,4′-biphenylene group.

In the general formula (A2-7), n^{a19} is an integer of 2 to 5, preferably an integer of 2 to 4, and more preferably 2 or 3.

Examples of the maleimide resin (A2) include an aromatic bismaleimide resin, an aromatic polymaleimide resin, and an aliphatic maleimide resin.

Specific examples of the maleimide resin (A2) include, for example, bis(4-maleimidophenyl) methane, polyphenylmethane maleimide, m-phenylenebismaleimide, 2,2-bis [4-(4-maleimidophenoxy)phenyl]propane, 4-methyl-1,3-phenylenebismaleimide, m-phenylenebismaleimide, 3,3′-dimethyl-5,5′-diethyl-4,4′-diphenylmethanebismaleimide, polyphenylmethanemaleimide, and biphenyl aralkyl-based maleimide. Among them, biphenyl aralkyl-based maleimide is preferred.

### (Maleimide Resin Derivative (AY))

The maleimide resin derivative (AY) is preferably an aminomaleimide resin having a structural unit derived from the maleimide resin (AX) mentioned above and a structural unit derived from a diamine compound.

The aminomaleimide resin has a structural unit derived from the maleimide resin (AX) and a structural unit derived from a diamine compound.

The aminomaleimide resin is obtained by, for example, allowing Michael addition to occur between the maleimide resin (AX) and a diamine compound.

Examples of the diamine compound that can be used are the same amine compounds each having at least two primary amino groups in one molecule as those mentioned in JP 2020-200406 A. Among them, 4,4′-diaminodiphenylmethane, 3,3′-dimethyl-4,4′-diaminodiphenylmethane, 3,3′-diethyl-4,4′-diaminodiphenylmethane, 2,2-bis [4-(4-aminophenoxy)phenyl]propane, 4,4′-[1,3-phenylenebis(1-methylethylidene)]bisaniline, 4,4′-[1,4-phenylenebis(1-methylethylidene]bisaniline, and 3,3′-diethyl-4,4′-diaminodiphenylmethane are preferred.

Among the above-described examples of the thermosetting resin (A), from the viewpoint of dielectric properties, conductor adhesion properties, and heat resistance, the thermosetting resin (A) is preferably a maleimide resin containing a condensed ring of an aromatic ring and an aliphatic ring in a molecular structure and having two or more N-substituted maleimide groups.

The thermosetting resin (A) preferably has a viscosity at 25° C. measured by the aforementioned method of more than 100,000 mPa·s, and more preferably is in a solid state at 25° C.

### (Content of Thermosetting Resin (A))

In the first resin composition, the content of the thermosetting resin (A) is not particularly limited, but it is preferably 5 to 60 mass %, more preferably 8 to 40 mass %, further preferably 10 to 30 mass %, and particularly preferably 15 to 25 mass %, relative to the total amount (100 mass %) of resin components in the first resin composition.

When the content of the thermosetting resin (A) is equal to or more than the lower limit value, heat resistance, moldability, processability, and conductor adhesion properties tend to be improved. When the content of the thermosetting resin (A) is equal to or less than the upper limit value, dielectric properties tend to be improved.

The upper limit value of the content of the thermosetting resin (A) may be 80 mass % or less, 70 mass % or less, or 60 mass % or less, relative to the total amount (100 mass %) of the thermosetting resin (A) and the reactive liquid compound (B). The lower limit value of the content of the thermosetting resin (A) may be 5 mass % or more, 10 mass % or more, or 15 mass % or more, relative to the total amount (100 mass %) of the thermosetting resin (A) and the reactive liquid compound (B).

In the present specification, a “resin component” means a resin and a compound that forms a resin by a curing reaction.

In the first resin composition, for example, the component (A) and the component (B) correspond to resin components.

When the first resin composition contains, in addition to the aforementioned components, a resin or a compound that forms a resin through a curing reaction as an optional component, the optional component is also included in the resin components. Examples of the optional component corresponding to a resin component include a component (D), a component (E), and the like described later.

On the other hand, the component (C) is not included in the resin components. The content of the resin components in the first resin composition is not particularly limited, but from the viewpoint of low thermal expansivity, heat resistance, flame retardance, and conductor adhesion properties, it is preferably 5 to 80 mass %, more preferably 10 to 60 mass %, and further preferably 20 to 40 mass %, relative to the total solid content (100 mass %) of the first resin composition.

The content of the maleimide-based resin in the thermosetting resin (A) is not particularly limited, but it is preferably 80 to 100 mass %, more preferably 90 to 100 mass %, and further preferably 95 to 100 mass %, relative to the total amount (100 mass %) of the thermosetting resin (A).

When the content of the maleimide-based resin is equal to or more than the lower limit value, heat resistance, moldability, processability, and conductor adhesion properties tend to be improved. When the content of the maleimide-based resin is equal to or less than the upper limit value, dielectric properties tend to be improved.

### <Reactive Liquid Compound (B)>

The reactive liquid compound (B) is not particularly limited as long as it is a compound that is in a liquid state at 25° C., has a reactive group, and has a molecular weight of 1,000 or less.

The reactive liquid compound (B) may be used alone, or may be used in combination of two or more types.

The reactive liquid compound (B) preferably has two or more reactive groups, more preferably two to five reactive groups, further preferably two to four reactive groups, and particularly preferably two or three reactive groups in one molecule.

When the number of reactive groups falls within the aforementioned range, excellent flexibility tend to be easily achieved and simultaneously volatilization during heating and curing is effectively suppressed.

The molecular weight of the reactive liquid compound (B) is 1,000 or less, preferably 100 to 800, more preferably 150 to 600, and further preferably 200 to 400.

When the molecular weight of the reactive liquid compound (B) is equal to or more than the lower limit value, volatilization of the reactive liquid compound (B) before the first resin composition is heated and cured tends to be easily suppressed. When the molecular weight of the reactive liquid compound (B) is equal to or less than the upper limit value, more excellent flexibility tends to be easily achieved.

The viscosity at 25° C. of the reactive liquid compound (B) is preferably 1 to 5,000 mPa·s, more preferably 2 to 1,000 mPa·s, and further preferably 4 to 500 mPa s.

When the viscosity at 25° C. of the reactive liquid compound (B) is equal to or more than the lower limit value, volatilization of the reactive liquid compound (B) tends to be easily suppressed. When the viscosity at 25° C. of the reactive liquid compound (B) is equal to or less than the upper limit value, more excellent flexibility tends to be easily achieved.

The viscosity at 25° C. of the reactive liquid compound (B) can be measured by the measurement method mentioned above.

The reactive liquid compound (B) preferably has, as the reactive group, one or more selected from a functional group having an ethylenically unsaturated bond, an epoxy group, a hydroxy group, a carboxy group, and an amino group.

In the present specification, an “ethylenically unsaturated bond” means a carbon-carbon double bond to which addition reaction can be made, and does not include an aromatic ring double bond.

Examples of the functional group having an ethylenically unsaturated bond include a vinyl group, an allyl group, a 1-methylallyl group, an isopropenyl group, a 2-butenyl group, a 3-butenyl group, a styryl group, an N-substituted maleimide group, and a (meth)acryloyl group.

Among them, the reactive group is more preferably a functional group having an ethylenically unsaturated bond or an epoxy group, further preferably, from the viewpoint of easily achieving more excellent dielectric properties, a functional group having an ethylenically unsaturated bond, and particularly preferably a (meth)acryloyl group.

Specific examples of the reactive liquid compound (B) having, as the reactive group, a (meth)acryloyl group include a (meth)acrylate such as a mono(meth)acrylate, a di(meth)acrylate, or a (meth)acrylate having three or more functional groups.

Examples of the mono(meth)acrylate include methyl (meth)acrylate, ethyl (meth)acrylate, propyl (meth)acrylate, butyl (meth)acrylate, pentyl (meth)acrylate, hexyl (meth)acrylate, heptyl (meth)acrylate, 2-ethylhexyl (meth)acrylate, octyl (meth)acrylate, isooctyl (meth)acrylate, nonyl (meth)acrylate, decyl (meth)acrylate, dodecyl (meth)acrylate, lauryl (meth)acrylate, tridecyl (meth)acrylate, stearyl (meth)acrylate, cyclohexyl (meth)acrylate, cyclopentyl (meth)acrylate, benzyl (meth)acrylate, dicyclopentenyl (meth)acrylate, dicyclopentenyloxyethyl (meth)acrylate, methoxyethyl (meth)acrylate, ethoxyethyl (meth)acrylate, butoxyethyl (meth)acrylate, phenoxyethyl (meth)acrylate, 2-hydroxyethyl (meth)acrylate, 2-hydroxypropyl (meth)acrylate, and 4-hydroxybutyl (meth)acrylate.

Examples of the di(meth)acrylate include 1,4-butanediol di(meth)acrylate, 1,6-hexanediol di(meth)acrylate, 1,9-nonanediol di(meth)acrylate, 1,10-decanediol di(meth)acrylate, tricyclodecane di(meth)acrylate, 1,12-dodecanediol di(meth)acrylate, ethylene glycol di(meth)acrylate, diethylene glycol di(meth)acrylate, triethylene glycol di(meth)acrylate, polyethylene glycol di(meth)acrylate, propylene glycol di(meth)acrylate, dipropylene glycol di(meth)acrylate, tripropylene glycol di(meth)acrylate, polypropylene glycol di(meth)acrylate, neopentyl glycol di(meth)acrylate, ethoxylated bisphenol A di(meth)acrylate, ethoxylated bisphenol F di(meth)acrylate, and dioxane glycol di(meth)acrylate.

Examples of dioxane glycol di(meth)acrylate include 2-[5-ethyl-5-[(acryloyloxy)methyl]-1,3-dioxan-2-yl]-2,2-dimethylethyl acrylate.

Examples of the (meth)acrylate having three or more functional groups include trimethylolpropane tri(meth)acrylate, pentaethritol tri(meth)acrylate, and dipentaerythritol hexa(meth)acrylate.

Among the options mentioned above, the (meth)acrylate is preferably a di(meth)acrylate.

The di(meth)acrylate is preferably a diacrylate represented by the following general formula (B-1) or a dimethacrylate represented by the following general formula (B-2), and more preferably a dimethacrylate represented by the following general formula (B-2).

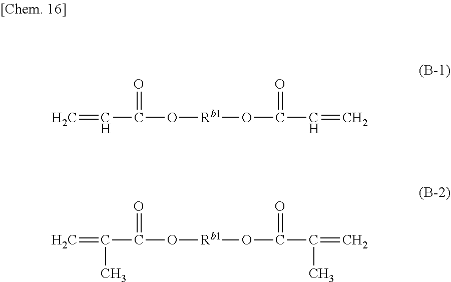

wherein R^{b1} is an alkylene group having 1 to 20 carbon atoms.

From the viewpoint of flexibility and volatilization suppression, the number of carbon atoms in the alkylene group having 1 to 20 carbon atoms represented by R^{b1} in the general formulae (B-1) and (B-2) is preferably 4 to 18, more preferably 6 to 15, and further preferably 8 to 12.

Examples of the alkylene group having 1 to 20 carbon atoms include a methylene group, an ethylene group, a propylene group, a butylene group, a pentylene group, a hexylene group, a heptylene group, an octylene group, a nonylene group, a decylene group, an undecylene group, a dodecylene group, a tetradecylene group, and a pentadecylene group. The alkylene group may be linear, branched, or cyclic, and preferably is linear.

### (Content of Reactive Liquid Compound (B))

In the first resin composition, the content of the reactive liquid compound (B) is not particularly limited, but it is preferably 5 to 60 mass %, more preferably 8 to 40 mass %, further preferably 10 to 30 mass %, and particularly preferably 15 to 25 mass %, relative to the total amount (100 mass %) of the resin components in the first resin composition.

In the first resin composition, the content of the reactive liquid compound (B) is not particularly limited, but it is preferably 0.5 to 20 mass %, more preferably 1.0 to 15 mass %, and further preferably 1.5 to 10 mass %, relative to the total solid content (100 mass %) of the first resin composition.

When the content of the reactive liquid compound (B) is equal to or more than the lower limit value, more excellent flexibility tends to be easily achieved. When the content of the reactive liquid compound (B) is equal to or less than the upper limit value, generation of a volatile component during heating and curing tends to be easily suppressed.

### <Inorganic Filler (C)>

By virtue of containing the inorganic filler (C), the first resin composition is likely to easily achieve more excellent low thermal expansivity, heat resistance, and flame retardance.

In particular, since the resin film of the embodiment is excellent in flexibility, it allows further improvement of low thermal expansivity by increasing the content of the inorganic filler (C).

The inorganic filler (C) may be used alone, or may be used in combination of two or more types.

Examples of the inorganic filler (C) include silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, talc, aluminum borate, and silicon carbide. Among them, from the viewpoint of low thermal expansivity, heat resistance, and flame retardance, silica, alumina, mica, and talc are preferred, and silica and alumina are more preferred.

Examples of the silica include precipitated silica produced by a wet process and having a high moisture content and dry process silica produced by a dry process and containing little bound water. Specific examples of the dry process silica include crushed silica, fumed silica, and molten silica, which vary in production method.

From the viewpoint of improving dispersibility and adhesion to organic components, the inorganic filler (C) may have been surface-treated with a surface treatment agent such as a silane coupling agent.

The mean particle diameter of the inorganic filler (C) is not particularly limited, but from the viewpoint of dispersibility of the inorganic filler (C) and fine patternability, it is preferably 0.01 to 20 μm, more preferably 0.1 to 10 μm, further preferably 0.2 to 1 μm, and particularly preferably 0.3 to 0.8 μm.

In the present specification, a mean particle diameter is a particle diameter of a point corresponding to 50% by volume on a distribution curve of particle diameter cumulative frequencies where the total volume of particles is 100%. The mean particle diameter can be measured with, for example, a particle size distribution measuring device using a laser diffraction scattering method.

The inorganic filler (C) has a spherical shape or a crushed shape, for example, and preferably a spherical shape.

### (Content of Inorganic Filler (C))

In the first resin composition, the content of the inorganic filler (C) is not particularly limited, but it is preferably 20 to 95 mass %, more preferably 40 to 90 mass %, and further preferably 60 to 80 mass %, relative to the total solid content (100 mass %) of the first resin composition.

When the content of the inorganic filler (C) is equal to or more than the lower limit value, low thermal expansivity, heat resistance, and flame retardance tend to be easily improved. When the content of the inorganic filler (C) is equal to or less than the upper limit value, moldability and conductor adhesion properties tend to be easily improved.

### <Elastomer Having Molecular Weight of More Than 1,000 (D)>

The first resin composition preferably further contains the elastomer having a molecular weight of more than 1,000 (D) [hereinafter sometimes referred to as “elastomer (D).”].

When the first resin composition contains the elastomer (D), more excellent dielectric properties tend to be easily achieved.

The “elastomer” used herein means a polymer having a glass transition temperature of 25° C. or lower measured by differential scanning calorimetry in accordance with JIS K 6240:2011.

The elastomer (D) may be used alone, or may be used in combination of two or more types.

The molecular weight of the elastomer (D) is more than 1,000, preferably 1,050 to 500,000, more preferably 1,100 to 350,000, and further preferably 1,150 to 200,000.

When the molecular weight of the elastomer (D)) is equal to or more than the lower limit value, heat resistance and the like of the resulting first resin composition tend to be easily kept favorably. When the molecular weight of the elastomer (D)) is equal to or less than the upper limit value, dielectric properties and conductor adhesion properties of the resulting first resin composition tend to be easily improved.

Preferred examples of the elastomer (D) include a conjugated diene polymer (D1), a modified conjugated diene polymer (D2), and a styrene-based elastomer (D3).

Hereinafter, preferred aspects of these components will be described.

### (Conjugated Diene Polymer (D1))

In the present specification, a “conjugated diene polymer” means a polymer of conjugated diene compound.

When the first resin composition contains the conjugated diene polymer (D1), more excellent dielectric properties tend to be easily achieved.

The conjugated diene polymer (D1) may be used alone, or may be used in combination of two or more types.

Examples of the conjugated diene compound include 1,3-butadiene, isoprene, 1,3-pentadiene, 2,3-dimethyl-1,3-butadiene, 2-phenyl-1,3-butadiene, and 1,3-hexadiene.

The conjugated diene polymer (D1) may be a polymer of one type of conjugated diene compounds or may be a copolymer of two or more types of conjugated diene compounds.

The conjugated diene polymer (D1) may be a copolymer of one or more types of conjugated diene compounds and monomers other than the one or more types of conjugated diene compounds.

When the conjugated diene polymer (D1) is a copolymer, its polymerization type is not particularly limited, and may be any one of random polymerization, block polymerization, and graft polymerization.

From the viewpoint of compatibility with other resins and dielectric properties, the conjugated diene polymer (D1) is preferably a conjugated diene polymer having a plurality of vinyl groups in side chains.

The number of vinyl groups in one molecule of the conjugated diene polymer (D1) is not particularly limited, but from the viewpoint of compatibility with other resins and dielectric properties, it is preferably 3 or more, more preferably 5 or more, and further preferably 10 or more.

The upper limit of the number of vinyl groups in one molecule of the conjugated diene polymer (D1) is not particularly limited, and may be 100 or less, 80 or less, or 60 or less.

Examples of the conjugated diene polymer (D1) include a polybutadiene having a 1,2-vinyl group, a butadiene-styrene copolymer having a 1,2-vinyl group, and a polyisoprene having a 1,2-vinyl group. Among them, from the viewpoint of dielectric properties and heat resistance, a polybutadiene having a 1,2-vinyl group and a butadiene-styrene copolymer having a 1,2-vinyl group are preferred, and a polybutadiene having a 1,2-vinyl group is more preferred. The polybutadiene having a 1,2-vinyl group is preferably a polybutadiene homopolymer having a 1,2-vinyl group.

The 1,2-vinyl group derived from butadiene in the conjugated diene polymer (D1) is a vinyl group contained in a butadiene-derived structural unit represented by the following formula (D1-1).

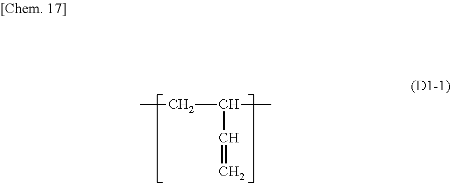

When the conjugated diene polymer (D1) is a polybutadiene having a 1,2-vinyl group, the content of the structural unit having a 1,2-vinyl group relative to all the structural units derived from butadiene constituting the polybutadiene [hereinafter sometimes referred to as “vinyl group content.”] is not particularly limited, but from the viewpoint of compatibility with other resins, dielectric properties, and heat resistance, it is preferably 50 mol % or more, more preferably 70 mol % or more, and further preferably 85 mol % or more. The upper limit of the vinyl group content is not particularly limited, and may be 100 mol % or less, 95 mol % or less, or 90 mol % or less. The structural unit having a 1,2-vinyl group is preferably the butadiene-derived structural unit represented by the formula (D1-1).

From the same viewpoint, the polybutadiene having a 1,2-vinyl group is preferably a 1,2-polybutadiene homopolymer.

The number average molecular weight of the conjugated diene polymer (D1) is not particularly limited, but from the viewpoint of compatibility with other resins, dielectric properties, and heat resistance, it is preferably 1,050 to 3,000, more preferably 1,100 to 2,000, and further preferably 1,150 to 1,500.

### (Modified Conjugated Diene Polymer (D2))

The modified conjugated diene polymer (D2) is a polymer obtained by modifying a conjugated diene polymer.

When the first resin composition contains the modified conjugated diene polymer (D2), more excellent dielectric properties tend to be easily achieved while possessing favorable heat resistance and low thermal expansivity.

The modified conjugated diene polymer (D2) may be used alone, or may be used in combination of two or more types.

For example, when the thermosetting resin (A) contains a maleimide-based resin, from the viewpoint of compatibility with other resins, dielectric properties, and conductor adhesion properties, the modified conjugated diene polymer (D2) is preferably a modified conjugated diene polymer obtained by modifying a conjugated diene polymer having a vinyl group in a side chain (d1) [hereinafter sometimes referred to as “conjugated diene polymer (d1).”] with a maleimide resin having two or more N-substituted maleimide groups (d2) [hereinafter sometimes referred to as “maleimide resin (d2).”].

As the conjugated diene polymer (d1), for example, the conjugated diene polymer having a vinyl group in a side chain described as the conjugated diene polymer (D1) can be used; the same applies to preferred aspects.

The conjugated diene polymer (d1) may be used alone, or may be used in combination of two or more types.

As the maleimide resin (d2), for example, the maleimide resin having two or more N-substituted maleimide groups described as the maleimide resin (AX) can be used; the same applies to preferred aspects.

The maleimide resin (d2) may be used alone, or may be used in combination of two or more types.

The modified conjugated diene polymer (D2) preferably has, in a side chain, a substituent [hereinafter sometimes referred to as “substituent (x).”] obtained by a reaction between the vinyl group in the conjugated diene polymer (d1) and the N-substituted maleimide groups in the maleimide resin (d2).

From the viewpoint of compatibility with other resins, dielectric properties, low thermal expansivity, and heat resistance, the substituent (x) is preferably a group having a structure represented by the following general formula (D2-1) or (D2-2) as a structure derived from the maleimide resin (d2).

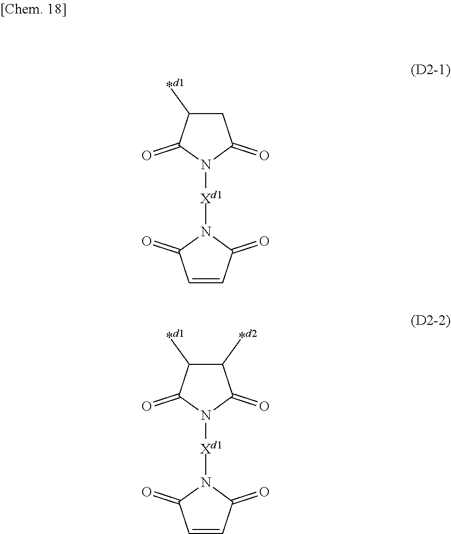

wherein X^{d1} is a divalent group obtained by removing two N-substituted maleimide groups from the maleimide resin (d2); *^{d1} is a site at which the conjugated diene polymer (d1) bonds to a carbon atom derived from a vinyl group in a side chain; and *^{d2} is a site for bonding to another atom.

The modified conjugated diene polymer (D2) preferably has the substituent (x) and a vinyl group (y) in side chains.

To know the proportion of the substituent (x) in the modified conjugated diene polymer (D2), the ratio of vinyl groups modified with the maleimide resin (d2) to vinyl groups in the conjugated diene polymer (d1) [hereinafter sometimes referred to as “vinyl group modification rate.”] can be used as an index.

The vinyl group modification rate is not particularly limited, but from the viewpoint of compatibility with other resins, dielectric properties, low thermal expansivity, and heat resistance, it is preferably 20 to 70%, more preferably 30 to 60%, and further preferably 35 to 50%. The vinyl group modification rate used herein is a value obtained by the method described in Examples.

The vinyl group (y) is preferably a 1,2-vinyl group in a butadiene-derived structural unit.

The number average molecular weight of the modified conjugated diene polymer (D2) is not particularly limited, but from the viewpoint of compatibility with other resins, dielectric properties, low thermal expansivity, and heat resistance, it is preferably 1,100 to 6,000, more preferably 1,300 to 4,000, and further preferably 1,500 to 2,000.

The modified conjugated diene polymer (D2) can be produced by allowing the conjugated diene polymer (d1) to react with the maleimide resin (d2).

A method for reacting the conjugated diene polymer (d1) with the maleimide resin (d2) is not particularly limited. For example, the modified conjugated diene polymer (D2) may be obtained by causing a reaction to occur by placing the conjugated diene polymer (d1), the maleimide resin (d2), a reaction catalyst, and an organic solvent in a reaction vessel and performing heating, keeping the temperature, stirring, and the like as necessary.

From the viewpoint of workability and suppression of gelation of a product during the reaction, the reaction temperature for the reaction is preferably 70 to 120° C., more preferably 80 to 110° C., and further preferably 85 to 105° C.

From the viewpoint of productivity and sufficient promotion of the reaction, the reaction time of the reaction is preferably 0.5 to 15 hours, more preferably 1 to 10 hours, and further preferably 3 to 7 hours.

It should be noted that these reaction conditions may be appropriately adjusted depending on the types of raw materials to use and the like, and are not particularly limited.

The ratio (Mₘ/Mᵥ) of the number of moles (Mₘ) of the N-substituted maleimide group in the maleimide resin (d2) to the number of moles (Mᵥ) of the side-chain vinyl group in the conjugated diene polymer (d1) in the reaction is not particularly limited, but from the viewpoint of compatibility of the resulting modified conjugated diene polymer (D2) with other resin and suppression of gelation of a product during the reaction, it is preferably 0.001 to 0.5, more preferably 0.005 to 0.1, and further preferably 0.008 to 0.05.

### <Styrene-Based Elastomer (D3)>

The styrene-based elastomer (D3) is not particularly limited as long as it is an elastomer having a styrene-based-compound-derived structural unit.

When the first resin composition contains the styrene-based elastomer (D3), more excellent dielectric properties tend to be easily achieved.

The styrene-based elastomer (D3) may be used alone, or may be used in combination of two or more types.

The styrene-based elastomer (D3) preferably has a styrene-based-compound-derived structural unit represented by the following general formula (D3-1).

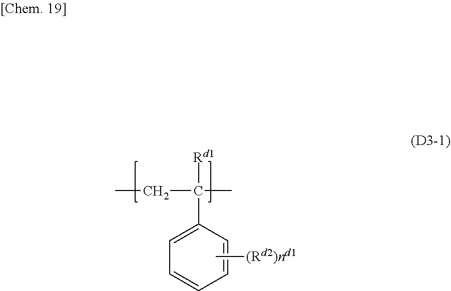

wherein R^{d1} is a hydrogen atom or an alkyl group having 1 to 5 carbon atoms; R^{d2} is an alkyl group having 1 to 5 carbon atoms; and n^{d1} is an integer of 0 to 5.

Examples of the alkyl group having 1 to 5 carbon atoms represented by R^{d1} and R^{d2} in the general formula (D3-1) include a methyl group, an ethyl group, a n-propyl group, an isopropyl group, a n-butyl group, an isobutyl group, a t-butyl group, and a n-pentyl group. The alkyl group having 1 to 5 carbon atoms may be linear or branched. Among them, an alkyl group having 1 to 3 carbon atoms is preferred, an alkyl group having 1 or 2 carbon atoms is more preferred, and a methyl group is further preferred.

In the general formula (D3-1), n^{d1} is an integer of 0 to 5, preferably an integer of 0 to 2, more preferably 0 or 1, and further preferably 0.

The styrene-based elastomer (D3) may contain a structural unit other than the styrene-based-compound-derived structural unit.

Examples of the structural unit other than styrene-based-compound-derived structural unit that may be contained in the styrene-based elastomer (D3) include a butadiene-derived structural unit, an isoprene-derived structural unit, a maleic-anhydride-derived structural unit, and a maleic-anhydride-derived structural unit.

The butadiene-derived structural unit and the isoprene-derived structural unit may be hydrogenated. When hydrogenated, the butadiene-derived structural unit is a structural unit in which an ethylene unit and a butylene unit are mixed, while the isoprene-derived structural unit is a structural unit in which an ethylene unit and a propylene unit are mixed.

Examples of the styrene-based elastomer (D3) include a hydrogenated styrene-butadiene-styrene block copolymer, a hydrogenated styrene-isoprene-styrene block copolymer, and a styrene maleic anhydride copolymer.

Examples of the hydrogenated styrene-butadiene-styrene block copolymer include SEBS where carbon-carbon double bonds in a butadiene block are completely hydrogenated and SBBS where the carbon-carbon double bond of 1,2-binding site in a butadiene block is partially hydrogenated. The complete hydrogenation in SEBS is typically 90% or more of all carbon-carbon double bonds; it may be 95% or more, 99% or more, or 100%. The partial hydrogenation rate in SBBS is, for example, 60 to 85% of all carbon-carbon double bonds. The hydrogenated styrene-isoprene-styrene block copolymer is obtained as SEPS where a polyisoprene block is hydrogenated.

Among them, from the viewpoint of dielectric properties, conductor adhesion properties, heat resistance, glass transition temperature, and low thermal expansivity, SEBS and SEPS are preferred, and SEBS is more preferred.

In the styrene-based elastomer (D3), the content of the styrene-based-compound-derived structural unit [hereinafter sometimes referred to as “styrene content.”] is not particularly limited, but it is preferably 5 to 60 mass %, more preferably 7 to 40 mass %, and further preferably 10 to 20 mass %.

The melt flow rate (MFR) of the styrene-based elastomer (D3) is not particularly limited, but under measurement conditions of 230° C. and a load of 2.16 kgf (21.2 N), it is preferably 0.1 to 20 g/10 min, more preferably 1 to 10 g/10 min, and further preferably 3 to 7 g/10 min.

The number average molecular weight of the styrene-based elastomer (D3) is not particularly limited, but it is preferably 10,000 to 500,000, more preferably 50,000 to 350,000, and further preferably 100,000 to 200,000.

Examples of the elastomer (D) other than the conjugated diene polymer (D1), the modified conjugated diene polymer (D2), and the styrene-based elastomer (D3) include a polyolefin resin, a polyphenylene ether resin, a polyester resin, a polyamide resin, and a polyacrylic resin other than these.

### (Content of Elastomer (D))

When the first resin composition contains the elastomer (D), the content of the elastomer (D) is not particularly limited, but it is preferably 10 to 80 mass %, more preferably 30 to 70 mass %, and further preferably 50 to 60 mass %, relative to the total amount (100 mass %) of the resin components in the first resin composition.

When the content of the elastomer (D) is equal to or more than the lower limit value, more excellent dielectric properties tend to be easily achieved. When the content of the elastomer (D) is equal to or less than the upper limit value, more excellent heat resistance tends to be easily achieved.

The total content of one or more selected from a group consisting of the conjugated diene polymer (D1), the modified conjugated diene polymer (D2), and the styrene-based elastomer (D3) is not particularly limited, but from the viewpoint of dielectric properties and conductor adhesion properties, it is preferably 60 to 100 mass %, more preferably 80 to 100 mass %, and further preferably 90 to 100 mass %, relative to the total amount (100 mass %) of the elastomer (D).

### <Curing Accelerator (E)>

The first resin composition preferably further contains the curing accelerator (E).

When the first resin composition contains the curing accelerator (E), more excellent dielectric properties, heat resistance, and conductor adhesion properties tend to be easily achieved.

The curing accelerator (E) may be used alone, or may be used in combination of two or more types.

From the viewpoint of efficiently forming chemical bonds of resin components during heating, the curing accelerator (E) preferably contains a radical polymerization initiator. The radical polymerization initiator acts as a polymerization initiator for radical polymerization, and is decomposed into species having unpaired electrons when exposed to energy such as light or heat. Examples of the radical polymerization initiator include organic peroxides, inorganic peroxides, and azo compounds described later, and an organic peroxide is preferred.

Examples of the curing accelerator (E) include an acid catalyst such as p-toluenesulfonic acid; an amine compound such as triethylamine, pyridine, tributylamine, or dicyandiamide; an imidazole compound such as methylimidazole, phenylimidazole, or 1-cyanoethyl-2-phenylimidazole; an isocyanate-masked imidazole compound such as an addition reaction product of a hexamethylene diisocyanate resin and 2-ethyl-4-methylimidazole; a tertiary amine compound; a quaternary ammonium compound; a phosphorous-containing compound such as triphenyl phosphine; an organic peroxide such as dicumyl peroxide, 2,5-dimethyl-2,5-bis (t-butylperoxy) hexine-3,2,5-dimethyl-2,5-bis (t-butylperoxy) hexane, t-butylperoxy isopropyl monocarbonate, or 1,3-di (t-butylperoxy isopropyl)benzene; an inorganic peroxide such as potassium persulfate, sodium persulfate, or ammonium persulfate; an azo compound such as 2,2′-azobisisobutylonitrile, 2,2′-azobis(2,4-dimethylvaleronitrile), or 2,2′-azobis(4-methoxy-2′-dimethylvaleronitrile); and a carboxylic acid salt of manganese, cobalt, zinc, or the like.

Among them, from the viewpoint of a curing acceleration effect and storage stability, an imidazole compound, an isocyanate-masked imidazole compound, an organic peroxide, and a carboxylic acid salt are preferred, and an isocyanate-masked imidazole compound and an organic peroxide are more preferred.

When the first resin composition contains the curing accelerator (E), the content of the curing accelerator (E) is not particularly limited, but it is preferably 0.1 to 15 parts by mass, more preferably 1 to 10 parts by mass, and further preferably 4 to 8 parts by mass, relative to the total amount (100 parts by mass) of the thermosetting resin (A) and the reactive liquid compound (B).

When the content of the curing accelerator (E) is equal to or more than the lower limit value, sufficient curing acceleration effect tends to be easily achieved. When the content of the curing accelerator (E) is equal to or less than the upper limit value, storage stability tends to be improved.

When the first resin composition contains, as the curing accelerator (E), a radical polymerization initiator, the content of the radical polymerization initiator is not particularly limited, but it is preferably 0.05 to 7 parts by mass, more preferably 0.5 to 5 parts by mass, and further preferably 2 to 4 parts by mass, relative to the total amount (100 parts by mass) of the thermosetting resin (A) and the reactive liquid compound (B).

When the content of the radical polymerization initiator is equal to or more than the lower limit value, sufficient curing acceleration effect tends to be easily achieved and generation of a volatile component tends to be easily suppressed. When the content of the radical polymerization initiator is equal to or less than the upper limit value, storage stability tends to be improved.

### <Other Components>

The first resin composition may further contain one or more optional components selected from a group consisting of a resin material other than the aforementioned components, a flame retarder, an antioxidant, a thermal stabilizer, an antistat, an ultraviolet absorber, a pigment, a colorant, a lubricant, an organic solvent, and the other additives as necessary.

Each of the optional components may be used alone, or may be used in combination of two or more types.

The content of the optional component in the first resin composition is not particularly limited, and may be used as necessary within a range not impairing the effects of the embodiment.

The first resin composition may not contain the optional component depending on desired performance.

Each of the aforementioned components that may be contained in the first resin composition may be contained also in the second resin composition described later.

In particular, unless otherwise specified, the description given above about the component (A) can be interpreted as description about a component (F) described later.

Unless otherwise specified, the description given above about the component (B) can be interpreted as description about a component (G) described later.

Unless otherwise specified, the description given above about the component (C) can be interpreted as description about a component (H) described later.

Unless otherwise specified, the description given above about the component (D) can be interpreted as description about a component (I) described later.

Unless otherwise specified, the description given above about the component (E) can be interpreted as description about a component (J) described later.

In the description given above about the first resin composition, “first resin composition” can be interpreted as “second resin composition” as necessary.

### <Thickness of Insulation-Member-Forming Resin Layer>

The thickness of the insulation-member-forming resin layer is not particularly limited and may be determined depending on use application, but from the viewpoint of effectively leveraging the excellent flexibility feature of the resin film of the embodiment, it is preferably 10 μm or more, more preferably 40 μm or more, further preferably 60 μm or more, and particularly preferably 80 μm or more.

The thickness of the insulation-member-forming resin layer is not particularly limited, but from the viewpoint of cost efficiency and flexibility, it is preferably 1,000 μm or less, more preferably 500 μm or less, further preferably 300 μm or less, and particularly preferably 200 μm or less.

### <<Primer-Layer-Forming Resin Layer>>

It is preferable that the primer-layer-forming resin layer in the resin film of the embodiment contain the second resin composition and the second resin composition be formed as a layer.

The second resin composition preferably contains one or more selected from a group consisting of the thermosetting resin (F), the compound that is in a liquid state at 25° C., has a reactive group, and has a molecular weight of 1,000 or less (G) [hereinafter sometimes referred to as “reactive liquid compound (G).”], and the inorganic filler (H).

### <Thermosetting Resin (F)>

When the second resin composition contains the thermosetting resin (F), more excellent heat resistance tends to be easily achieved.

Description about types of the thermosetting resin (F) is the same as that of the thermosetting resin (A).

In the second resin composition, the content of the thermosetting resin (F) is not particularly limited, but it is preferably 5 to 60 mass %, more preferably 10 to 50 mass %, further preferably 15 to 40 mass %, and particularly preferably 20 to 30 mass %, relative to the total amount (100 mass %) of resin components in the second resin composition.

When the content of the thermosetting resin (F) is equal to or more than the lower limit value, heat resistance, moldability, processability, and conductor adhesion properties tend to be improved. When the content of the thermosetting resin (F) is equal to or less than the upper limit value, dielectric properties tend to be improved.

The upper limit value of the content of the thermosetting resin (F) may be 80 mass % or less, 70 mass % or less, or 60 mass % or less, relative to the total amount (100 mass %) of the thermosetting resin (F) and the reactive liquid compound (G). The lower limit value of the content of the thermosetting resin (F) may be 5 mass % or more, 10 mass % or more, or 15 mass % or more, relative to the total amount (100 mass %) of the thermosetting resin (F) and the reactive liquid compound (G).

### <Reactive Liquid Compound (G)>

When the second resin composition contains the reactive liquid compound (G), more excellent flexibility tends to be easily achieved.

Description about types of the reactive liquid compound (G) is the same as that of the reactive liquid compound (B).

In the second resin composition, the content of the reactive liquid compound (G) is not particularly limited, but it is preferably 5 to 60 mass %, more preferably 8 to 40 mass %, further preferably 10 to 30 mass %, and particularly preferably 15 to 25 mass %, relative to the total amount (100 mass %) of the resin components in the second resin composition.

In the second resin composition, the content of the reactive liquid compound (G) is not particularly limited, but it is preferably 5 to 30 mass %, more preferably 10 to 25 mass %, and further preferably 15 to 20 mass %, relative to the total solid content (100 mass %) of the second resin composition.

When the content of the reactive liquid compound (G) is equal to or more than the lower limit value, more excellent flexibility tends to be easily achieved. When the content of the reactive liquid compound (G) is equal to or less than the upper limit value, generation of a volatile component during heating and curing tends to be easily suppressed.

### <Inorganic Filler (H)>

When the second resin composition contains the inorganic filler (H), more excellent low thermal expansivity tends to be easily achieved.

Description about types of the inorganic filler (H) is the same as that of the inorganic filler (C).

It is preferable that the second resin composition contain the inorganic filler (H), the content by mass of the inorganic filler (H) in the second resin composition being smaller than the content by mass of the inorganic filler (C) in the first resin composition, and further contain the thermosetting resin (F) and the reactive liquid compound (G).

The content of the inorganic filler (H) in the second resin composition is not particularly limited, but it is preferably 1 to 30 mass %, more preferably 3 to 20 mass %, and further preferably 5 to 15 mass %, relative to the total solid content (100 mass %) of the second resin composition.

When the content of the inorganic filler (H) is equal to or more than the lower limit value, low thermal expansivity tends to be easily improved. When the content of the inorganic filler (H) is equal to or less than the upper limit value, plating property tends to be easily improved.

The difference [(1)-(2)] between the content by mass (1) of the inorganic filler (C) relative to the total solid content (100 mass %) of the first resin composition in the first resin composition and the content by mass (2) of the inorganic filler (H) relative to the total solid content (100 mass %) of the second resin composition in the second resin composition is not particularly limited, but it is preferably 30 to 90 mass %, more preferably 40 to 80 mass %, and further preferably 50 to 70 mass %.

When the difference [(1)-(2)] falls within the aforementioned range, both low thermal expansivity and plating property tend to be easily achieved simultaneously.

The mean particle diameter of the inorganic filler (H) is not particularly limited, but it is preferably 0.005 to 0.1 μm, more preferably 0.01 to 0.05 μm, and further preferably 0.015 to 0.02 μm.

When the mean particle diameter of the inorganic filler (H) falls within the aforementioned range, plating property tends to be easily improved.

The content of the resin components in the second resin composition is not particularly limited, but it is preferably 60 to 97 mass %, more preferably 70 to 95 mass %, and further preferably 85 to 92 mass %, relative to the total solid content (100 mass %) of the second resin composition.

When the content of the resin components in the second resin composition falls within the aforementioned range, plating property tends to be easily improved.

The resin components in the second resin composition are the component (F), the component (G), the component (I), the component (J), and the like; the component (H) is not included in the resin components.

### <Elastomer Having Molecular Weight of More Than 1,000 (I)>

The second resin composition preferably further contains the elastomer having a molecular weight of more than 1,000 (I) [hereinafter sometimes referred to as “elastomer (I).”].

When the second resin composition contains the elastomer (I), more excellent dielectric properties tend to be easily achieved.

Description about types of the elastomer (I) is the same as that of the elastomer (D).

In the second resin composition, the content of the elastomer (I) is not particularly limited, but it is preferably 10 to 80 mass %, more preferably 30 to 70 mass %, and further preferably 50 to 60 mass %, relative to the total amount (100 mass %) of the resin components in the second resin composition.

When the content of the elastomer (I) is equal to or more than the lower limit value, more excellent dielectric properties tend to be easily achieved. When the content of the elastomer (I) is equal to or less than the upper limit value, more excellent heat resistance tends to be easily achieved.

### <Curing Accelerator (J)>

The second resin composition preferably further contains the curing accelerator (J).

When the second resin composition contains the curing accelerator (J), more excellent dielectric properties, heat resistance, and conductor adhesion properties tend to be easily achieved.

Description about types of the curing accelerator (J) is the same as that of the curing accelerator (E).

In the second resin composition, the content of the curing accelerator (J) is not particularly limited, but it is preferably 0.1 to 15 parts by mass, more preferably 0.5 to 10 parts by mass, and further preferably 1 to 5 parts by mass, relative to the total amount (100 parts by mass) of the thermosetting resin (F) and the reactive liquid compound (G).

When the content of the curing accelerator (J) is equal to or more than the lower limit value, sufficient curing acceleration effect tends to be easily achieved. When the content of the curing accelerator (J) is equal to or less than the upper limit value, storage stability tends to be improved.

When the second resin composition contains, as the curing accelerator (J), a radical polymerization initiator, the content of the radical polymerization initiator is not particularly limited, but it is preferably 0.05 to 7 parts by mass, more preferably 0.1 to 5 parts by mass, and further preferably 0.5 to 2 parts by mass, relative to the total amount (100 parts by mass) of the thermosetting resin (F) and the reactive liquid compound (G).

When the content of the radical polymerization initiator is equal to or more than the lower limit value, sufficient curing acceleration effect tends to be easily achieved and generation of a volatile component tends to be easily suppressed. When the content of the radical polymerization initiator is equal to or less than the upper limit value, storage stability tends to be improved.

### <Other Components>

The second resin composition may further contain the aforementioned other components that may be contained in the first resin composition.

### <Thickness of Primer-Layer-Forming Resin Layer>

The thickness of the primer-layer-forming resin layer is not particularly limited, but it is preferably 0.2 to 20 μm, more preferably 0.5 to 10 μm, further preferably 1 to 5 μm, and particularly preferably 1.5 to 3 μm.

When the thickness of the primer-layer-forming resin layer is equal to or more than the lower limit value, plating property tends to be easily improved. When the thickness of the primer-layer-forming resin layer is equal to or less than the upper limit value, low thermal expansivity tends to be easily improved.

The resin film of the embodiment may have another layer between the insulation-member-forming resin layer and the primer-layer-forming resin layer, but an aspect in which the insulation-member-forming resin layer and the primer-layer-forming resin layer are directly laminated to each other is preferred.

The resin film of the embodiment may have a layer other than the insulation-member-forming resin layer and the primer-layer-forming resin layer, but preferably has only the insulation-member-forming resin layer and the primer-layer-forming resin layer.

The resin film of the embodiment may be formed on a support, and may have a protective film on its surface. It should be noted the support and the protective film are not encompassed in the concept of the resin film.

### <Thickness of Resin Film>

The thickness of the resin film is not particularly limited, but from the viewpoint of effectively leveraging the excellent flexibility feature of the resin film of the embodiment, it is preferably 15 μm or more, more preferably 45 μm or more, further preferably 65 μm or more, and particularly preferably 85 μm or more.

The thickness of the resin film of the embodiment is not particularly limited, but it is preferably 1,020 μm or less, more preferably 510 μm or less, further preferably 305 μm or less, and particularly preferably 203 μm or less.

### <Solvent Content of Resin Film>

The content of the organic solvent in the resin film of the embodiment is preferably 2 mass % or less, more preferably 1 mass % or less, further preferably 0.5 mass % or less, or may be 0 mass %, relative to the total amount (100 mass %) of the resin film.

When the content of the organic solvent in the resin film falls within the aforementioned range, the amount of the organic solvent that volatilizes during heating and curing tends to be easily suppressed sufficiently.

### <170° C. Mass Reduction Rate of Resin Film>

The mass reduction rate during heating and drying in an air atmosphere at 170° C. for 30 minutes [hereinafter sometimes referred to as “170° C. mass reduction rate.”] of the resin film of the embodiment is preferably 2.0 mass % or less, more preferably 1.5 mass % or less, further preferably 1.0 mass % or less, or may be 0 mass %.

When the 170° C. mass reduction rate falls within the aforementioned range, the amount of volatile component during heating and curing tends to be easily suppressed sufficiently.

The 170° C. mass reduction rate can be measured by the method described in Examples.

### <Dielectric Properties of Cured Product of Resin Film>

The relative dielectric constant (Dk) at 10 GHz of a cured product of the resin film of the embodiment may be less than 3.0, less than 2.9, or less than 2.8. The smaller the relative dielectric constant (Dk), the more preferred it is; the lower limit value thereof is not particularly limited, but it may be, for example, 2.4 or more or 2.5 or more with balance with other physical properties taken into account.

The dielectric loss tangent (Df) at 10 GHz of the cured product of the resin film of the embodiment may be less than 0.0040, less than 0.0035, or less than 0.0030. The smaller the dielectric loss tangent (Df), the more preferred it is; the lower limit value thereof is not particularly limited, and may be, for example, 0.0010 or more or 0.0015 or more with balance with other physical properties taken into account.

The relative dielectric constant (Dk) and the dielectric loss tangent (Df) are values in conformity with a cavity resonator perturbation method and, more specifically, values measured by the method described in Examples.

The resin film of the embodiment is suitable as, for example, a resin film for forming an insulation layer of a printed wiring board such as a multilayer printed wiring board or a resin film for semiconductor encapsulation of a semiconductor package.

### <Method for Producing Resin Film>

A method for producing the resin film of the embodiment is not particularly limited; the production may be, for example, by a method of forming a primer-layer-forming resin layer on a support and forming an insulation-member-forming resin layer on the primer-layer-forming resin layer.

The primer-layer-forming resin layer can be produced by, for example, applying a second resin composition containing an organic solvent [hereinafter the second resin composition containing an organic solvent may be referred to as “second resin varnish.”] to the support, and then heating and drying it.

Examples of the support include a plastic film, a metal foil, and a release paper.

Examples of the plastic film include a film of polyolefin such as polyethylene, polypropylene, or polyvinyl chloride; a film of polyester such as polyethylene terephthalate [hereinafter sometimes referred to as “PET.”] or polyethylene naphthalate; a polycarbonate film; and a polyimide film. Among them, from the viewpoint of cost efficiency and ease of handling, a polyethylene terephthalate film is preferred.

Examples of the metal foil include a copper foil and an aluminum foil. When a copper foil is used as the support, the copper foil may be used as it is as a conductor layer for forming a circuit. In this case, as the copper foil, a rolled copper foil, an electrolytic copper foil, or the like may be used. When a thin copper foil is used, a copper foil with carrier may be used from the viewpoint of improving workability.

The support may have been subjected to surface treatment such as matte finishing or corona treatment. The support may have been subjected to release treatment with a silicone resin-based release agent, an alkyd resin-based release agent, a fluororesin-based release agent, or the like.

The thickness of the support is not particularly limited, but from the viewpoint of ease of handling and cost efficiency, it is preferably 10 to 150 μm, more preferably 20 to 100 μm, and further preferably 25 to 50 μm.

As a coater for applying the second resin varnish, a coater known to those skilled in the art such as a comma coater, a bar coater, a kiss coater, a roll coater, a gravure coater, or a die coater may be used. Selection from these coaters may be made appropriately depending on the thickness of the film to be formed.

Conditions for drying the second resin varnish after applying it are not particularly limited, and may be appropriately determined depending on the content, boiling point, and the like of the organic solvent.

For example, for a second resin varnish containing 30 to 50 mass % of aromatic hydrocarbon-based solvent, the drying temperature is not particularly limited, but from the viewpoint of productivity and curing the second resin composition to an appropriate extent to B-stage, it is preferably 50 to 200° C., more preferably 80 to 150° C., and further preferably 100 to 130° C.

For the aforementioned second resin varnish, the drying time is not particularly limited, but from the viewpoint of productivity and curing the second resin composition to an appropriate extent to B-stage, it is preferably 1 to 30 minutes, more preferably 2 to 15 minutes, and further preferably 3 to 10 minutes.

Subsequently, a first resin composition containing an organic solvent [hereinafter the first resin containing an organic solvent is sometimes referred to as “first resin varnish.”] is applied onto the primer-layer-forming resin layer formed as described above and then heated and dried to thereby form the insulation-member-forming resin layer on the primer-layer-forming resin layer; thus, the resin film of the embodiment can be obtained.

Examples of a coater for applying the first resin varnish are the same as those of the coater for applying the second resin varnish.

Conditions for drying the first resin varnish after applying it are not particularly limited, and may be appropriately determined depending on the content, boiling point, and the like of the organic solvent.

For example, for a first resin varnish containing 40 to 60 mass % of aromatic hydrocarbon-based solvent, the drying temperature is not particularly limited, but from the viewpoint of productivity and curing the first resin composition to an appropriate extent to B-stage, it is preferably 50 to 200° C., more preferably 80 to 150° C., and further preferably 100 to 130° C.

For the aforementioned first resin varnish, the drying time is not particularly limited, but from the viewpoint of productivity and curing the first resin composition to an appropriate extent to B-stage, it is preferably 1 to 30 minutes, more preferably 2 to 15 minutes, and further preferably 3 to 10 minutes.

### [Printed Wiring Board]

A printed wiring board of the embodiment is a printed wiring board including a cured product of the resin film of the embodiment.

The printed wiring board of the embodiment preferably includes: a circuit substrate; an insulation layer, in which a circuit of the circuit substrate is to be embedded, formed of a cured product of the insulation-member-forming resin layer in the resin film of the embodiment; a primer layer provided on the insulation layer on a side opposite to the circuit substrate and formed of the primer-layer-forming resin layer in the resin film of the embodiment; and a circuit provided on the primer layer on a side opposite to the insulation layer.

An aspect of a method for manufacturing the printed wiring board of the embodiment is described below.

When manufacturing a printed wiring board using the resin film of the embodiment, firstly, the resin film of the embodiment is laminated to one side or each of both sides of a circuit substrate with the insulation-member-forming resin layer facing the circuit substrate.

Examples of the circuit substrate include a glass epoxy substrate, a metal substrate, a polyester substrate, a polyimide substrate, a BT resin substrate, and a thermosetting polyphenylene ether substrate, each having a patterned conductor layer formed on one side or both sides.

Subsequently, the circuit substrate to which the resin film is laminated is heated to cure the insulation-member-forming resin layer to form an insulation layer in which a circuit of the circuit substrate is to be embedded.

The heating temperature for heating and curing is not particularly limited, but it is preferably 100 to 300° C., more preferably 120 to 280° C., and further preferably 150 to 250° C.

The heating time for heating and curing is not particularly limited, but it is preferably 2 to 300 minutes, more preferably 5 to 200 minutes, and further preferably 10 to 150 minutes.

The insulation layer formed by the aforementioned method has, on the side opposite to the circuit substrate, a primer layer formed of the primer-layer-forming resin layer.

Thereafter, perforation may be performed as necessary.

The perforation is a step of perforating the circuit substrate where the insulation layer and the primer layer are formed using, for example, a drill, a laser, plasma, a combination thereof, or other means to provide a via hole, a through hole, or the like. Examples of the laser to be used in the perforation include a carbon dioxide gas laser, a YAG laser, a UV laser, and an excimer laser.

Subsequently, the surface of the primer layer may be roughened with an oxidant; when a via hole, a through hole, or the like has been provided, a so-called “smear” generated when providing it may be removed with an oxidant. The roughening and desmearing may be carried out simultaneously.

Subsequently, a conductor layer is formed on the roughened surface of the primer layer by plating.

Example of the plating include electroless plating and electrolytic plating. Examples of metal for plating include copper, gold, silver, nickel, platinum, molybdenum, ruthenium, aluminum, tungsten, iron, titanium, chromium, and an alloy containing at least one of these metal elements. Among them, copper and nickel are preferred, and copper is more preferred.

As a method for patterning the conductor layer to form a circuit, a known method such as a subtractive process, a full-additive process, a semi-additive process (SAP), and a modified semi-additive process (m-SAP), for example, may be used.

It is also possible to manufacture a multilayer printed wiring board by repeating necessary steps as appropriate.

### [Semiconductor Package]

A semiconductor package of the embodiment is a semiconductor package including a cured product of the resin film of the embodiment.

The semiconductor package of the embodiment may be one manufactured by mounting a semiconductor chip on the printed wiring board of the embodiment, for example. The semiconductor chip may be mounted on the printed wiring board by a known method.

The semiconductor package of the embodiment may be one manufactured by encapsulating a semiconductor chip with a cured product of the resin film of the embodiment, for example.

Encapsulation of a semiconductor chip with the resin film may be performed by, for example, after placing the resin film on the semiconductor chip with the insulation-member-forming resin layer in contact therewith, heating and melting the resin film to embed the semiconductor chip, and heating and curing the resin film as it is.

### EXAMPLES

Hereinafter, the embodiment is described specifically by way of Examples. It should be noted that the embodiment is not limited to the following Examples.

### (Method for Measuring Number Average Molecular Weight)

The number average molecular weights were calculated from a calibration curve using standard polystyrene by gel permeation chromatography (GPC). The calibration curve was approximated by a cubic equation using standard polystyrene: TSKstandard POLYSTYRENE (Type: A-2500, A-5000, F-1, F-2, F-4, F-10, F-20, F-40) (manufactured by TOSOH CORPORATION, trade names). GPC measurement conditions are given below.

### [GPC Measurement Conditions]

Device: high-performance GPC system HLC-8320GPC
Detector: ultraviolet absorbance detector UV-8320 [manufactured by TOSOH CORPORATION]
Columns: guard column: TSK Guardcolumn SuperHZ-L; columns: TSKgel SuperHZM-N+TSKgel SuperHZM-M+TSKgel SuperH-RC (all manufactured by TOSOH CORPORATION, trade names)
Column size: 4.6×20 mm (guard column), 4.6×150 mm (column), 6.0×150 mm (reference column)
Eluent: tetrahydrofuran
Sample concentration: 10 mg/5 ml
Injection volume: 25 μL
Flow rate: 1.00 mL/min
Measurement temperature: 40° C.

### [Production of Modified Conjugated Diene Polymer]

### Production Example 1

In a 2-L heatable and coolable glass flask equipped with a thermometer, a reflux condenser, and a stirrer, 33.8 parts by mass of 1,2-polybutadiene homopolymer (number average molecular weight=1,200, vinyl group content=85% or more), 1.43 parts by mass of aromatic bismaleimide resin containing an indane ring (the compound represented by the general formula (A1-4-1), number average molecular weight=1,300), 0.0035 parts by mass of t-butyl peroxy isopropyl carbonate, and toluene as an organic solvent were placed. Subsequently, they were stirred in a nitrogen atmosphere at 90 to 100° C. for five hours to allow them to react; thus, a solution of modified conjugated diene polymer (solid content concentration: 35 mass %) was obtained. The number average molecular weight of the obtained modified conjugated diene polymer was 1,700.

GPC of a solution containing 1,2-polybutadiene homopolymer and aromatic bismaleimide resin containing an indane ring before initiation of the reaction and that of the solution after the reaction were measured using the aforementioned method to determine peak areas derived from the aromatic bismaleimide resin containing an indane ring before and after the reaction. Subsequently, a vinyl group modification rate of the aromatic bismaleimide resin containing an indane ring was calculated using the following equation. The vinyl group modification rate corresponds to the reduction rate of the peak area derived from the aromatic bismaleimide resin containing an indane ring due to the reaction.

Vinyl group modification rate (%)=[(peak area derived from aromatic bismaleimide resin containing indane ring before initiation of reaction)−(peak area derived from aromatic bismaleimide resin containing indane ring after completion of reaction)]×100/(peak area derived from aromatic bismaleimide resin containing indane ring before initiation of reaction)

The vinyl group modification rate determined using the equation was 40%.

### [Production of Resin Film]

### Examples 1 and 2

### (Production of First and Second Resin Compositions)

The components listed in Table 1 were blended with toluene in accordance with the blending amounts listed in Table 1, and then stirred and mixed under heating at 25° C. or to 50 to 80° C., thereby prepared a first resin composition having a solid content concentration of approximately 50 mass % and a second resin composition having a solid content concentration of approximately 38 mass %. In Table 1, the unit for blending amount of each component is parts by mass, and that for a solution means parts by mass on a solid content basis.

### (Production of Resin Film)

The second resin composition obtained in each Example was applied to one side of a 50-μm-thick PET film (manufactured by TOYOBO CO., LTD., trade name “Purex A53”) such that the thickness of the primer-layer-forming resin layer after drying achieved the thickness given in Table 1. Thereafter, the second resin composition was cured to B-stage by heating and drying it at 105° C. for five minutes; thus, the primer-layer-forming resin layer was formed on the PET film.

Subsequently, the first resin composition obtained in each Example was applied onto the primer-layer-forming resin layer such that the thickness of the insulation-member-forming resin layer after drying achieved the thickness given in Table 1. Thereafter, the first resin composition was cured to B-stage by heating and drying it at 105° C. for five minutes; thus, the insulation-member-forming resin layer was formed on the primer-layer-forming resin layer. A resin film with PET film on one side (thickness of the resin film: 100 μm) having the PET film, the primer-layer-forming resin layer, and the insulation-member-forming resin layer in this order was prepared in this manner.

Next, the obtained resin film with PET film on one side was cut out into 200 mm×200 mm pieces, which were overlaid on one another with the resin films facing each other. Subsequently, the pieces were bonded to each other using a vacuum laminator at a temperature of 100° C. for a pressing time of five seconds; thus, a resin film with PET film on both sides (the thickness of the resin film was 200 μm) was obtained.

(Production of Resin Plate with Copper Foil on Both Sides)

The obtained resin film with PET film on both sides was cut out into a piece of 90 mm in length and 50 mm in width, and the PET film was removed by peeling from each side. A 0.2-mm-thick Teflon (registered trademark) sheet die-cut into a size of 90 mm in length and 50 mm in width was placed on a copper foil, the resin film from which the PET films were peeled off was put on the die-cut portion and, furthermore, a copper foil was placed thereon to obtain a laminate. As the copper foil, a low-profile copper foil having a thickness of 18 μm (manufactured by MITSUI MINING & SMELTING CO., LTD., trade name “3EC-VLP-18”) was used, and it was placed such that its matte side faces the resin film. Subsequently, the laminate was molded by heating and pressing it under temperature, pressure, and time conditions of 180° C., 2.0 MPa, and 60 minutes to cure the resin film while molding it into a resin plate; thus, a resin plate with copper foil on both sides was prepared. The thickness of the resin plate portion of the obtained resin plate with copper foil on both sides was 0.2 mm.

(Production of Laminate Plate with Cured Resin Layer on Both Sides)

The resulting resin film with PET film on one side was stacked on both sides of a CZ-treated, double-sided copper clad laminate plate (manufactured by Resonac Corporation, trade name “MCL-E-700GR”) by lamination such that the resin film and the copper clad laminate plate were in contact with each other. The lamination was performed by a method of, after reducing the pressure at 100° C. for 15 seconds, applying a pressure of 0.5 MPa for 45 seconds, and subsequently performing pressing at 130° C. for 60 seconds with a press-bonding pressure of 0.5 MPa.

Subsequently, the laminate plate in which the resin film with PET film on one side was laminated on each side was heated in an explosion-proof dryer at 180° C. for 60 minutes to cure the resin films. Thereafter, by removing the PET films from the both sides, a laminate plate with cured resin layer on both sides having a cured resin layer formed by curing the resin film on each side was obtained. The cured resin layer has an insulation layer, which is a cured product of the insulation-member-forming resin layer, on the side adjacent to the double-sided copper clad laminate plate and has the primer layer on the exposed side.

### Comparative Example 1

A resin film with PET film on one side (thickness of the resin film: 100 μm) in which the insulation-member-forming resin layer was formed on one side of the PET film was prepared In the same manner as in Example 1 except for that the primer-layer-forming resin layer was not formed. Using the resin film with PET film on one side, a resin plate with copper foil on both sides and a laminate plate with cured resin layer on both sides were prepared in the same manner as in Example 1.

### [Measurement and Evaluation Methods]

Measurement and evaluation were performed using resin films with PET film on one side, resin plates with copper foil on both sides, and laminate plates with cured resin layer on both sides obtained in Examples and Comparative Example in accordance with the following methods. The results are shown in Table 1.

### (1. Method for Evaluating Flexibility)

The resin film with PET film on one side obtained in each Example was wound around a resin cylinder having a diameter of 85 mm with the resin film surface facing outward at 25° C. The appearance of the wound resin film was visually observed and evaluated against the following criteria. In the following criteria, “A” means most excellent.

### <Criteria for Flexibility>

A: None of a crack in the resin film and peeling from the PET film was observed.

B: Either a crack in the resin film or peeling from the PET film was observed.

### (2. Method for Measuring and Evaluating Linear Expansion Coefficient and Glass Transition Temperature)

The resin plate with copper foil on both sides obtained in each Example was immersed in a 10 mass % solution of ammonium persulfate (manufactured by MITSUBISHI GAS CHEMICAL COMPANY, INC.), which was a copper etchant, to remove the copper foil. A test piece was produced by cutting out a piece of 0.4 mm in width and 20 mm in length from the obtained resin plate and then drying it at 105° C. for one hour. Both longitudinal ends of the test piece were gripped with upper and lower jaws with a clearance of 10 mm between the jaws. Subsequently, a dimensional change was determined using a thermo-mechanical analyzer (TMA) (manufactured by Seiko Instruments Inc., trade name “SS6100”) in a tensile mode at a temperature range of 30 to 300° C., with a temperature increasing rate of 5° C./min, and a load of 4 g. A glass transition temperature and a linear expansion coefficient were evaluated against the following criteria, in which the glass transition temperature is the inflection point of the dimensional change with respect to the temperature, and the linear expansion coefficient is the mean value of dimensional changes per unit temperature at 30 to 150° C. In the following criteria, “A” means most excellent.

### <Criteria for Linear Expansion Coefficient>

A: less than 20 ppm/K
B: 20 ppm/K or more and less than 40 ppm/K

### <Criteria for Glass Transition Temperature>

A: 180° C. or more
B: less than 180° C.

### (3. Method for Measuring and Evaluating Tensile Modulus of Elasticity at 25° C.)

The resin plate with copper foil on both sides obtained in each Example was immersed in a 10 mass % solution of ammonium persulfate (manufactured by MITSUBISHI GAS CHEMICAL COMPANY, INC.), which was a copper etchant, to remove the copper foil. A test piece was produced by cutting out a piece of 10 mm in width and 40 mm in length from the obtained resin plate and then drying it at 105° C. for one hour. Both longitudinal ends of the test piece were gripped with upper and lower jaws with a clearance of 20 mm between the jaws. Subsequently, the tensile modulus of elasticity of the test piece was determined using a compact table-top universal tester (manufactured by Shimadzu Corporation, trade name “EZ-TEST”) in an environment of 25° C. under a condition of a tensile speed of 2 mm/min. Five identical samples were prepared, the tensile moduli of elasticity of them were determined under the same conditions as mentioned above, and their mean value was determined as a tensile modulus of elasticity at 25° C. Other detailed conditions and the method for calculating the tensile modulus of elasticity were in accordance with international organization for standardization ISO 5271 (1993). The obtained tensile modulus of elasticity at 25° C. was evaluated against the following criteria. In the following criteria, “A” means most excellent.

### <Criteria for Tensile Modulus of Elasticity at 25° C.>

A: less than 1.5 GPa
B: 1.5 GPa or more

### (4. Method for Evaluating Plating Property)

The laminate plate with cured resin layer on both sides obtained in each Example was immersed in a swelling solution (manufactured by Atotech Japan K.K., trade name “Swelling Dip Securiganth P”) heated to 60° C. for 10 minutes. Next, immersion in a roughening solution (manufactured by Atotech Japan K.K., trade name “Concentrate Compact CP”) heated to 80° C. for 10 minutes was performed. Subsequently, neutralization was performed by performing immersion in a neutralizing solution (manufactured by Atotech Japan K.K., trade name “Reduction Solution Securiganth P500”) heated to 40° C. for five minutes. The surface of the cured resin layer was roughened in this manner.

Subsequently, degreasing cleaning was performed by performing treatment with an alkaline cleaner (manufactured by Atotech Japan K.K., trade name “Cleaner Securiganth 902”) at 60° C. for five minutes. After the cleaning, treatment with a predip solution (manufactured by Atotech Japan K.K., trade name “PreDip Neoganth B”) at 23° C. was performed for two minutes. Thereafter, treatment with an activator solution (manufactured by Atotech Japan K.K., trade name “Activator Neoganth 834”) at 40° C. was performed for five minutes to attach a palladium catalyst. Next, treatment with a reducing solution (manufactured by Atotech Japan K.K., trade name “Reducer Neoganth WA”) of 30° C. was performed for five minutes. Subsequently, electroless plating was performed by placing the laminate plate in a chemical copper solution (manufactured by Atotech Japan K.K., trade name “Basic Printoganth MSK-DK”) until the thickness of plating on the cured resin layer achieved 0.5 μm. After the electroless plating, baking was performed at 120° C. for 15 minutes to release residual stress in the plated film and remove residual hydrogen gas. Next, electrolytic plating was performed on the electroless-plated side to form a plated copper layer until the thickness of plating on the cured resin layer achieved 20 μm. After the electrolytic plating, the laminate plate was heated at 180° C. for 120 minutes.

The appearance of the obtained plated copper layer was visually observed and evaluated against the following criteria. In the following criteria, “A” means most excellent.

### <Criteria for Plating Property>

A: None of a blister and peeling is found on the plated copper layer.
B: Either a blister or peeling is found on the plated copper layer.

### (5. Method for Measuring and Evaluating Relative Dielectric Constant (Dk) and Dielectric Loss Tangent (Df))

The resin plate with copper foil on both sides obtained in each Example was immersed in a 10 mass % solution of ammonium persulfate (manufactured by MITSUBISHI GAS CHEMICAL COMPANY, INC.), which was a copper etchant, to remove the copper foil. A test piece was produced by cutting out a piece of 2 mm×50 mm from the obtained resin plate and then drying it at 105° C. for one hour. Subsequently, the relative dielectric constant (Dk) and the dielectric loss tangent (Df) of the test piece were measured at an atmosphere temperature of 25° C. in 10 GHz band in accordance with a cavity resonator perturbation method, and evaluated against the following criteria. In the following criteria, “A” means most excellent.

### <Criteria for Relative Dielectric Constant (Dk)>

A: less than 2.8
B: 2.8 or more

### <Criteria for Dielectric Loss Tangent (Df)>

A: 0.0025 or more and less than 0.0030
B: 0.0030 or more

### (6. Method for Measuring 170° C. Mass Reduction Rate)

An evaluation sample was prepared as B-stage powder by removing the PET film by peeling from the resin film with PET film on one side obtained in each Example and then grinding the resin film. Using the evaluation sample, a mass reduction rate during heating and drying in an air atmosphere at 170° C. for 30 minutes [{(mass before heating-mass after heating at 170° C. for 30 minutes)/(mass before heating)}×100] was determined as 170° C. mass reduction rate. The results are shown in Table 1. In Table 1, “≤1.0” indicates that the 170° C. mass reduction rate was 1.0 mass % or less.

TABLE 1

| | | | | | Comparative |
|---|---|---|---|---|---|
| | | | Examples | | Example |
| | | | 1 | 2 | 1 |
| Blend composition | Component (A) | Maleimide resin | 6.2 | 6.2 | 6.2 |
| of first resin | Component (B) | 1,9-nonanediol diacrylate | 6.2 | 6.2 | 6.2 |
| composition | Component (C) | Silica | 68.5 | 68.5 | 68.5 |
| (parts by mass) | Component (D) | Modified conjugated diene polymer | 6.2 | 6.2 | 6.2 |
| | | Styrene-based elastomer | 12.4 | 12.4 | 12.4 |
| | Component (E) | Organic peroxide | 0.4 | 0.4 | 0.4 |
| | | Imidazole-based curing accelerator | 0.4 | 0.4 | 0.4 |
| Blend composition | Component (F) | Maleimide resin | 21.5 | 21.5 | None |
| of second resin | Component (G) | 1,9-nonanediol diacrylate | 17.9 | 17.9 | |
| composition | Component (H) | Silica | 9.8 | 9.8 | |
| (parts by mass) | Component (I) | Modified conjugated diene polymer | 15.4 | 15.4 | |
| | | Styrene-based elastomer | 34.7 | 34.7 | |
| | Component (J) | Organic peroxide | 0.4 | 0.4 | |
| | | Imidazole-based curing accelerator | 0.4 | 0.4 | |

| Thickness of insulation-member-forming resin layer (μm) | | | 98 | 95 | 100 |
|---|---|---|---|---|---|
| Thickness of primer-layer-forming resin layer (μm) | | | 2 | 5 | None |
| Thickness of resin film (μm) | | | 100 | 100 | 100 |
| Evaluation | Flexibility | | A | A | A |
| results | Linear expansion coefficient | | A | B | A |
| | Glass transition temperature | | A | A | A |
| | Tensile modulus of elasticity at 25° C. | | A | A | A |
| | Plating property | | A | A | B |
| | Dielectric properties | Relative dielectric constant (Dk) | A | A | A |
| | (10 GHz) | Dielectric loss tangent (Df) | A | A | A |

| | | | |
|---|---|---|---|
| 170° C. mass reduction rate (mass %) | ≤1.0 | ≤1.0 | ≤1.0 |

Details of the components listed in Table 1 are as follows.

### [Component (A) and Component (F)]

Maleimide resin: aromatic bismaleimide resin containing an indane ring represented by the general formula (A1-4-1), number average molecular weight=1,300, solid state at 25° C.

### [Component (B) and Component (G)]

1,9-nonanediol diacrylate: liquid state at 25° C. (viscosity at 25° C.=8 mPa·s), molecular weight: 268.35

### [Component (C)]

Silica: spherical silica treated with an amino silane coupling agent, mean particle diameter: 0.5 μm

### [Component (D) and Component (I)]

Modified conjugated diene polymer: the modified conjugated diene polymer obtained in Production Example 1, number average molecular weight: 1,700

Styrene-based elastomer: hydrogenated styrene-based thermoplastic elastomer (styrene-ethylene-butylene-styrene copolymer); trade name “Tuftec H1221,” styrene content=12 mass %, MFR under measurement conditions of 230° C. and a load of 2.16 kgf=4.5 g/10 min, number average molecular weight=170,000

### [Component (E) and Component (J)]

Organic peroxide: 1,3-di (t-butylperoxy isopropyl)benzene Imidazole-based curing accelerator: isocyanate-masked imidazole, manufactured by DKS Co., Ltd., trade name “G-8009L”

### [Component (H)]

Silica: mean particle diameter: 0.016 μm

The above results show that the resin films of Examples 1 and 2 of the embodiment are excellent in flexibility, and their cured products are excellent in plating property. Furthermore, the resin films of Examples 1 and 2 have the 170° C. mass reduction rate of 1.0 mass % or less, which indicates that generation of a volatile component during heating and curing is suppressed. On the other hand, the resin film of Comparative Example 1 is inferior in plating property.

### INDUSTRIAL APPLICABILITY

The resin film of the embodiment can form a cured product having an excellent plating property and, while being excellent in flexibility, can suppress generation of a volatile component during heating and curing. Therefore, the resin film of the embodiment is useful for printed wiring boards, semiconductor packages, and the like.

1. A resin film comprising:
an insulation-member-forming resin layer containing a first resin composition; and
a primer-layer-forming resin layer provided on one side of the insulation-member-forming resin layer and containing a second resin composition,
the first resin composition containing a thermosetting resin (A), a compound that is in a liquid state at 25° C., has a reactive group, and has a molecular weight of 1,000 or less (B), and an inorganic filler (C).

2. The resin film according to claim 1, wherein the component (A) is one or more selected from a group consisting of a maleimide resin having one or more N-substituted maleimide groups and a derivative of the maleimide resin.

3. The resin film according to claim 2, wherein the maleimide resin having one or more N-substituted maleimide groups is a maleimide resin containing a condensed ring of an aromatic ring and an aliphatic ring in a molecular structure and having two or more N-substituted maleimide groups.

4. The resin film according to claim 1, wherein the component (B) has, as the reactive group, one or more selected from a functional group having an ethylenically unsaturated bond, an epoxy group, a hydroxy group, a carboxy group, and an amino group.

5. The resin film according to claim 1, wherein the component (B) has two or more of the reactive groups in one molecule.

6. The resin film according to claim 1, wherein the component (B) is a di(meth)acrylate.

7. The resin film according to claim 1, wherein a content of the component (B) relative to a total solid content (100 mass %) of the first resin composition is 0.5 to 20 mass %.

8. The resin film according to claim 1, wherein the second resin composition contains an inorganic filler (H), and a content by mass of the inorganic filler (H) in the second resin composition is smaller than a content by mass of the inorganic filler (C) in the first resin composition.

9. The resin film according to claim 8, wherein the second resin composition further contains a thermosetting resin (F) and a compound that is in a liquid state at 25° C., has a reactive group, and has a molecular weight of 1,000 or less (G).

10. The resin film according to claim 1, wherein the insulation-member-forming resin layer has a thickness of 80 μm or more.

11. The resin film according to claim 1, wherein the primer-layer-forming resin layer has a thickness of 0.2 to 20 μm.

12. The resin film according to claim 1, the resin film having a mass reduction rate during heating and drying in an air atmosphere at 170° C. for 30 minutes of 2.0 mass % or less.

13. A printed wiring board comprising a cured product of the resin film according to claim 1.

14. A semiconductor package comprising a cured product of the resin film according to claim 1.
